(19) United States
(12) Patent Application Publication
(10) Pub. No.: US 2026/0105965 A1
(43) Pub. Date: Apr. 16, 2026

(54) MEMORY DEVICE AND OPERATION METHOD THEREOF

(71) Applicant: Samsung Electronics Co., Ltd., Suwon-si (KR)

(72) Inventors: Kwangho Choi, Suwon-si (KR); Se Hwan Park, Suwon-si (KR); Soochang Lee, Suwon-si (KR); Taeyun Lee, Suwon-si (KR); Jongdae Hwang, Suwon-si (KR); Doohyun Kim, Suwon-si (KR); Seung-Bum Kim, Suwon-si (KR)

(21) Appl. No.: 19/331,600

(22) Filed: Sep. 17, 2025

(30) Foreign Application Priority Data
Oct. 15, 2024 (KR) 10-2024-0140449

(51) Int. Cl. G11C 16/14

(52) U.S. Cl. CPC G11C 16/14

(57) ABSTRACT

An example operation method of a memory device includes controlling, based on a 0-th bias condition, a first memory block, the 0-th bias condition corresponding to a 0-th GSL coding pattern of a plurality of ground selection lines connected with the first memory block, programming the plurality of ground selection lines of the first memory block to a first GSL coding pattern based on a program and erase cycle of the first memory block being a first reference value, and controlling the first memory block based on a first bias condition corresponding to the first GSL coding pattern. The 0-th and first bias conditions indicate voltages respectively applied to the plurality of ground selection lines connected with the first memory block.

### CROSS-REFERENCE TO RELATED APPLICATION

This application claims priority under 35 U.S.C. § 119 to Korean Patent Application No. 10-2024-0140449 filed on Oct. 15, 2024, in the Korean Intellectual Property Office, the disclosures of which are incorporated by reference herein in their entireties.

### BACKGROUND

A semiconductor memory is classified as a volatile memory, which loses data stored therein when a power is turned off, such as a static random access memory (SRAM) or a dynamic random access memory (DRAM) or a nonvolatile memory, which retains data stored therein even when a power is turned off, such as a flash memory, a phase-change RAM (PRAM), a magnetic RAM (MRAM), a resistive RAM (RRAM), or a ferroelectric RAM (FRAM).

The flash memory device is being widely used as a high-capacity storage medium. In general, the flash memory device stores data or read the stored data by controlling levels of various lines (e.g., a string selection line, a word line, and a ground selection line) connected to a plurality of memory cells. When various lines are controlled individually in units of cell string, the reliability and performance of the flash memory device may be improved, but it is difficult to form lines individually due to the increase in complexity of the process of manufacturing the flash memory device.

### SUMMARY

The present disclosure relates to a memory device with improved reliability and improved performance and an operation method thereof.

In some implementations, an operation method of a memory device includes controlling a first memory block, based on a 0-th bias condition corresponding to a 0-th GSL coding pattern of a plurality of ground selection lines connected to the first memory block, programming the plurality of ground selection lines of the first memory block to a first GSL coding pattern, when a program and erase cycle of the first memory block reaches a first reference value, and controlling the first memory block based on a first bias condition corresponding to the first GSL coding pattern, and the 0-th and first bias conditions indicate voltages respectively applied to the plurality of ground selection lines connected to the first memory block.

In some implementations, an operation method of a memory device includes performing an operation for a first memory block having a 0-th GSL coding pattern, updating the 0-th GSL coding pattern of the first memory block to a first GSL coding pattern, when a program and erase cycle of the first memory block reaches a first reference value, and performing an operation for the first memory block having the first GSL coding pattern. In the first memory block having the 0-th GSL coding pattern, at least one first ground selection transistor connected to a first ground selection line has a first threshold voltage state, at least one second ground selection transistor connected to a second ground selection line has the first threshold voltage state, and third ground selection transistors connected to a third ground selection line between the first and second ground selection lines have a second threshold voltage state lower than the first threshold voltage state. In the first memory block having the first GSL coding pattern, the at least one first ground selection transistor connected to the first ground selection line has the first threshold voltage state, the at least one second ground selection transistor connected to the second ground selection line has the first threshold voltage state, and at least one third ground selection transistor among the third ground selection transistors connected to the third ground selection line has the first threshold voltage state.

In some implementations, an operation method of a memory device includes performing an operation for a first memory block having a 0-th GSL coding pattern, updating the 0-th GSL coding pattern of the first memory block to a first GSL coding pattern, when a program and erase cycle of the first memory block reaches a first reference value, and performing an operation for the first memory block having the first GSL coding pattern. When the first memory block has the 0-th GSL coding pattern, at least one third ground selection line between a first ground selection line and a second ground selection line among a plurality of ground selection lines connected to the first memory block is a dummy ground selection line controlled regardless of a selected cell string among a plurality of cell strings of the first memory block. When the first memory block has the first GSL coding pattern, the at least one third ground selection line is a coding ground selection line controlled based on the selected cell string among the plurality of cell strings of the first memory block.

In some implementations, a memory device includes a substrate, a first memory block formed on the substrate, and a peripheral circuit that controls the first memory block. The first memory block includes a plurality of cell strings provided on the substrate between a common source line and a first bit line and connected to a plurality of ground selection lines. Each of the plurality of cell strings includes a plurality of ground selection transistors connected to the plurality of ground selection lines. When a program and erase cycle of the first memory block reaches a first reference value, the peripheral circuit controls a threshold voltage of each of the plurality of ground selection transistors.

In some implementations, a storage device includes a memory device including a first memory block connected to a plurality of ground selection lines, and a controller controlling the memory device. When a program and erase cycle of the first memory block reaches a first reference value, the controller performs a program operation for the plurality of ground selection lines such that a GSL coding pattern of the plurality of ground selection lines is updated.

### BRIEF DESCRIPTION OF THE DRAWINGS

The above and other objects and features of the present disclosure will become apparent by describing in detail implementations thereof with reference to the accompanying drawings.

FIG. 1 is a block diagram illustrating an example of a storage device.

FIG. 2 is a block diagram illustrating an example of a controller of FIG. 1.

FIG. 3 is a block diagram illustrating an example of a memory device of FIG. 1.

FIG. 4 is a circuit diagram illustrating an example of a first memory block included in a memory cell array of FIG. 3.

FIG. 5 is a plan view of an example of a first memory block of FIG. 4.

FIGS. 6A and 6B are diagrams for describing an example of a method of controlling a first memory block of FIGS. 4 and 5.

FIG. 7 is a flowchart illustrating an example of an operation of a memory device of FIG. 1.

FIG. 8 is a diagram for describing an example operation S130 of FIG. 7.

FIGS. 9A, 9B, 9C, 9D, and 9E are diagrams for describing an example of a GSL coding pattern change operation in operation S150 of FIG. 7.

FIGS. 10A and 10B are diagrams for describing an example of a bias condition for a first memory block having a 0-th GSL coding pattern.

FIGS. 11A and 11B are diagrams for describing an example of a bias condition for a first memory block having a first GSL coding pattern.

FIGS. 12A, 12B, 12C, 12D, 12E, and 12F are diagrams for describing various example GSL coding patterns of a first memory block.

FIGS. 13A and 13B are diagrams for describing an example of a GSL coding pattern of a first memory block.

FIGS. 14A and 14B are diagrams for describing an example of a bias condition according to a GSL coding pattern of a first memory block of FIG. 13A.

FIG. 15 is a flowchart illustrating an example of an operation of a memory device of FIG. 1.

FIGS. 16 and 17 are diagram for describing the update of an example of a GSL coding pattern according to the flowchart of FIG. 15.

FIGS. 18 and 19 are diagrams for describing an example of an operation of a memory device of FIG. 1.

FIG. 20 is a view for describing an example of a memory device.

FIG. 21 is a diagram illustrating an example of a system to which a storage device is applied.

### DETAILED DESCRIPTION

Below, implementations of the present disclosure will be described in detail and clearly to such an extent that an ordinary one in the art easily carries out the present disclosure.

In the detailed description or drawings, function blocks which are expressed by using the terms “unit”, “module”, etc. or are illustrated in drawings may be implemented in the form of hardware, software, or a combination thereof, which is configured to perform a specific function.

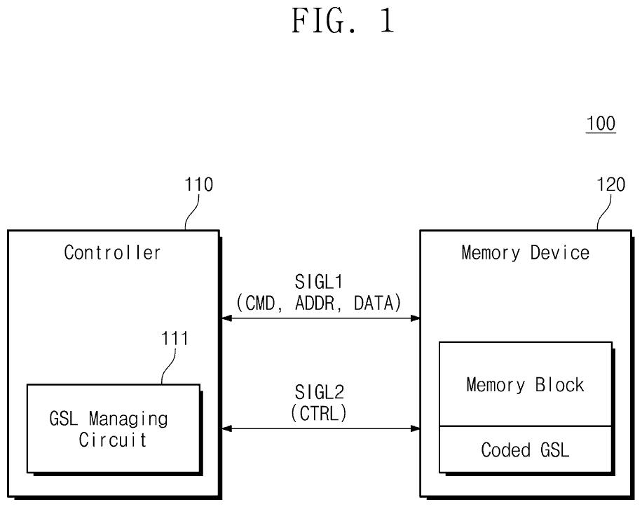

FIG. 1 is a block diagram illustrating an example of a storage device. Referring to FIG. 1, a storage device 100 may include a controller 110 and a memory device 120. In some implementations, the storage device 100 may be a high-capacity storage device, which is configured to store data in a computing system, such as a solid state drive (SSD) or a universal flash storage (UFS) card, but the present disclosure is not limited thereto. Alternatively, the storage device 100 may be a high-capacity storage medium included in a mobile system such as a mobile phone, a smartphone, a tablet personal computer (PC), a wearable device, a health care device, or an Internet of things (IoT) device. Alternatively, the storage device 100 may be a high-capacity storage medium included in the computer, a laptop computer, a server, a media player, an automotive device such as a navigation system, etc.

The controller 110 may be configured to control the memory device 120. For example, the controller 110 may store data in the memory device 120 or may read data stored in the memory device 120. For example, the controller 110 may transmit a command CMD and an address ADDR to the memory device 120 through first signal lines SIGL1 and may exchange data “DATA” with the memory device 120 through the first signal lines SIGL1. In some implementations, the first signal lines SIGL1 may be data signal lines (e.g., DQ lines). The controller 110 may transmit control signals CTRL to the memory device 120 through second signal lines SIGL2. In some implementations, the control signals CTRL may be used to classify signals transmitted/received through the first signal lines SIGL1 into the command CMD, the address ADDR, and the data “DATA”. However, the present disclosure is not limited thereto.

The memory device 120 may operate under control of the controller 110. For example, in response to the signals received from the controller 110, the memory device 120 may store data or may output data stored therein. In some implementations, the memory device 120 may include a NAND flash memory device, but the present disclosure is not limited thereto. For example, the memory device 120 may include various memories such as a dynamic random access memory (DRAM), a static RAM (SRAM), a phase-change RAM (PRAM), a magnetic RAM (MRAM), a resistive RAM (RRAM), or a ferroelectric RAM (FRAM).

In some implementations, the memory device 120 may include a plurality of memory blocks. Each of the plurality of memory blocks may include a coded GSL structure. For example, as will be described later, each of the plurality of memory blocks may include a plurality of cell strings sharing a ground selection line (GSL). Because the plurality of cell strings share the ground selection line, the performance of the memory device 120 may be reduced (e.g., a word line setup time may increase). To solve the above issue, threshold voltages of the ground selection transistors of each of the plurality of cell strings may be differently set, and voltages of ground selection lines may be controlled. According to this method, the plurality of cell strings may be individually controlled (i.e., only a selected cell string may be electrically connected to a common source line). A memory block with the coded GSL structure will be described in detail with reference to the following drawings.

In some implementations, the controller 110 may include a GSL managing circuit 111. The GSL managing circuit 111 may change a GSL coding pattern of the coded GSL structure (hereinafter, for convenience of description, referred to as a “GSL coding pattern”) of the memory device 120 depending on various conditions. For example, a threshold voltage of a ground selection transistor may change due to a physical characteristic (e.g., retention or hot electron injection) of the ground selection transistor. In this case, a plurality of cell strings may not be normally controlled through the control of ground selection lines, thereby making it difficult to normally read data (or user data) stored in a memory block or causing the reduction of performance of the memory device 120. To present the above issue, the GSL managing circuit 111 may change the GSL coding pattern, and thus, the reliability and performance of the memory device 120 may be improved.

As an example, in the early part of the lifetime of the memory device 120 (e.g., when a P/E cycle (e.g., of the memory device 120) is less than or equal to a reference value), threshold voltages of ground selection transistors may change due to the hot electron injection (HCI). Accordingly, in the early part of the lifetime of the memory device 120, the coded GSL structure may have a 0-th GSL coding pattern relatively robust for the hot electron injection. In the latter part of the lifetime of the memory device 120 (e.g., when a P/E cycle (e.g., of the memory device 120) is more than or equal to the reference value), the threshold voltages of the ground selection transistors may change due to the retention characteristic. Accordingly, in the latter part of the lifetime of the memory device 120, the coded GSL structure may have a first GSL coding pattern relatively robust for the retention characteristic. However, the present disclosure is not limited thereto. For example, the GSL coding pattern of the memory block may be variously changed or updated. As described above, as the GSL coding pattern of the memory device 120 is changed or updated, the reliability and performance of the memory device 120 may be improved.

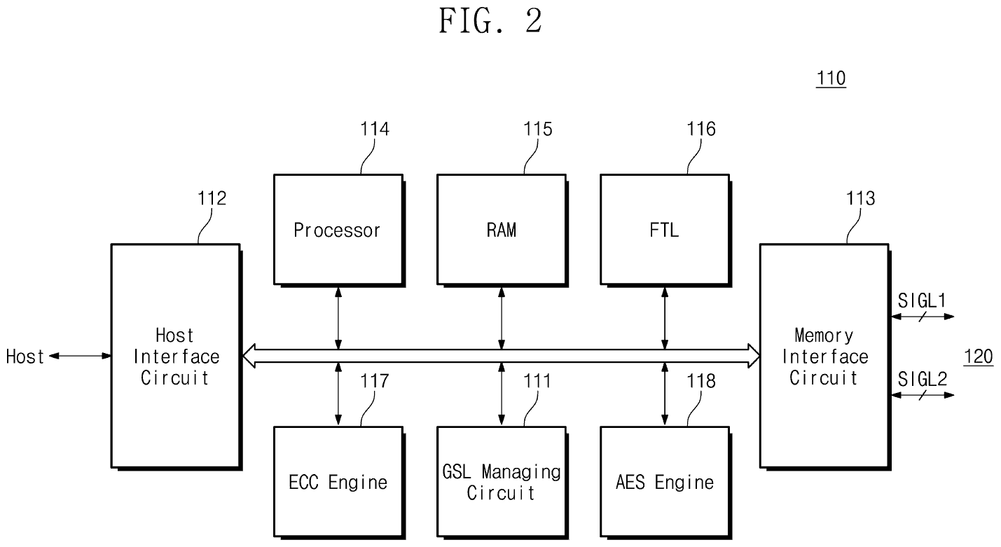

FIG. 2 is a block diagram illustrating an example of a controller of FIG. 1. Referring to FIGS. 1 and 2, the controller 110 may include the GSL managing circuit 111, a host interface circuit 112, a memory interface circuit 113, a processor 114, a random access memory (RAM) 115, a flash translation layer (FTL) 116, an error correction code (ECC) engine 117, and an advanced encryption standard (AES) engine 118.

The GSL managing circuit 111 may manage the coded GSL structure of the memory device 120. For example, the GSL managing circuit 111 may be configured to change the GSL coding pattern of the memory device 120. An operation of the GSL managing circuit 111 will be described in detail with reference to the following drawings.

The host interface circuit 112 may communicate with an external host based a host interface. In some implementations, the host interface may include at least one of various interfaces such as an ATA (Advanced Technology Attachment) interface, an SATA (Serial ATA) interface, an e-SATA (external SATA) interface, an SCSI (Small Computer Small Interface) interface, an SAS (Serial Attached SCSI) interface, a PCI (Peripheral Component Interconnection) interface, a PCIe (PCI express) interface, an NVMe (NVM express) interface, an IEEE 1394 interface, an USB (Universal Serial Bus) interface, an SD (Secure Digital) card interface, an MMC (Multi-Media Card) interface, an eMMC (embedded Multi-Media Card) interface, an UFS (Universal Flash Storage) interface, an eUFS (embedded Universal Flash Storage) interface, and a CF (Compact Flash) card interface.

The memory interface circuit 113 may communicate with the memory device 120 based on a memory interface. In some implementations, the memory interface may include one of interfaces such as a toggle interface and an open NAND flash interface (ONFI), and the first and second signal lines SIGL1 and SIGL2 may be configured to comply with the memory interface.

The processor 114 may control all the operations of the controller 110. For example, the processor 114 may execute various applications on the controller 110. The RAM 115 may be configured to store various information necessary for the controller 110 to operate. In some implementations, the RAM 115 may be used as a working memory, a cache memory, or a buffer memory of the controller 110.

The FTL 116 may perform maintenance operations for efficiently managing or using the memory device 120. In some implementations, the maintenance operations may include an address mapping operation, a wear-leveling operation, a garbage collection operation, etc.

The address mapping operation of the FTL 116 may refer to an operation of translating a logical address received from the external host into a physical address to be used to actually store data in the memory device 120. In some implementations, the FTL 116 may perform the address mapping operation by using L2P map data. The wear-leveling operation of the FTL 116 may refer to an operation of preventing excessive degradation of a specific memory block among the memory blocks included in the memory device 120. For example, the FTL 116 may allocate the memory blocks included in the memory device 120 so as to be used uniformly, and thus, the excessive degradation of the specific memory block may be prevented. In some implementations, the wear-leveling operation of the FTL 116 may be implemented through a firmware technology for balancing erase counts of the memory blocks of the memory device 120. The garbage collection operation of the FTL 116 may refer to an operation of securing a memory block or a capacity available in the memory devices 120 by copying valid data of a source memory block to a target memory block and then switching the source memory block into a free block or erasing the source memory block. The FTL 116 may further perform various management operations such as a bad block management operation, in addition to the above operations. In some implementations, a portion of or all of the functions of the FTL 116 may be implemented through software, hardware, or a combination thereof.

The ECC engine 117 may perform an error detection and correction function on data read from the memory device 120. For example, the ECC engine 117 may generate parity bits for write data to be written in the memory device 120, and the parity bits thus generated may be stored in the memory device 120 together with the write data. When data are read from the memory device 120, the ECC engine 117 may correct an error of the read data by using the parity bits read from the memory device 120 together with the read data and may output the error-corrected read data.

The AES engine 118 may perform at least one of an encryption operation and a decryption operation for data input to the controller 110 by using a symmetric-key algorithm.

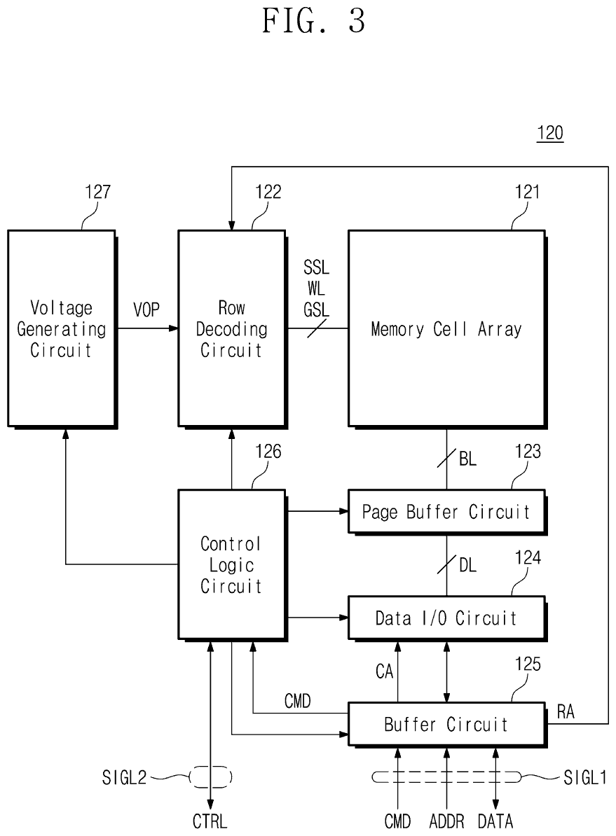

FIG. 3 is a block diagram illustrating an example of a memory device of FIG. 1. Referring to FIGS. 1 and 3, the memory device 120 may include a memory cell array 121, a row decoding circuit 122, a page buffer circuit 123, a data input/output (I/O) circuit 124, a buffer circuit 125, a control logic circuit 126, and a voltage generating circuit 127.

The memory cell array 121 may include a plurality of memory blocks. Each of the plurality of memory blocks may include a plurality of cell strings. Each of the plurality of cell strings may include a plurality of cell transistors stacked in a direction perpendicular to a substrate. The plurality of cell transistors may be connected in series between bit lines BL and a common source line. The plurality of cell transistors may be connected to string selection lines SSL, word lines WL, and ground selection lines GSL. In some implementations, each of the plurality of memory blocks may have the coded GSL structure, which will be described in detail with reference to the following drawings.

The row decoding circuit 122 may be connected to the memory cell array 121 through the string selection lines SSL, the word lines WL, and the ground selection lines GSL. The row decoding circuit 122 may operate under control of the control logic circuit 126. For example, under control of the control logic circuit 126, the row decoding circuit 122 may decode a row address RA received from the buffer circuit 125; based on a decoding result, the row decoding circuit 122 may control or drive the string selection lines SSL, the word lines WL, and the ground selection lines GSL or may control voltages to be applied to the string selection lines SSL, the word lines WL, and the ground selection lines GSL.

The page buffer circuit 123 may be connected to the memory cell array 121 through the bit lines BL. The page buffer circuit 123 may be connected to the data input/output circuit 124 through data lines DL. The page buffer circuit 123 may operate under control of the control logic circuit 126. For example, in the program operation of the memory device 120, the page buffer circuit 123 may control voltages of the bit lines BL based on data to be programmed in the memory cell array 121 under control of the control logic circuit 126. Alternatively, in the read operation of the memory device 120, the page buffer circuit 123 may sense voltages of the bit lines BL and may store the sensed voltages as read data.

The data input/output circuit 124 may be connected to the page buffer circuit 123 through the data lines DL. The data input/output circuit 124 may receive a column address CA from the buffer circuit 125. The data input/output circuit 124 may transmit the data read by the page buffer circuit 123 to the buffer circuit 125 depending on the column address CA. The data input/output circuit 124 may transmit the data received from the buffer circuit 125 to the page buffer circuit 123, based on the column address CA.

The buffer circuit 125 may receive the command CMD and the address ADDR through the first signal lines SIGL1 from the controller 110 and may exchange the data “DATA” with the controller 110 through the first signal lines SIGL1. In some implementations, the first signal lines SIGL1 may include signal lines for transmitting/receiving a data signal (e.g., DQ) and a data strobe signal (e.g., DQS).

The buffer circuit 125 may operate under control of the control logic circuit 126. For example, the control logic circuit 126 may exchange the control signals CTRL with the controller 110 through the second signal lines SIGL2. The control logic circuit 126 may control the buffer circuit 125 based on the control signals CTRL such that the buffer circuit 125 routes the command CMD, the address ADDR, and the data “DATA”. Under control of the control logic circuit 126, the buffer circuit 125 may classify signals received through the first signal lines SIGL1 as the command CMD or the address ADDR. The buffer circuit 125 may transfer the command CMD to the control logic circuit 126. The buffer circuit 125 may transfer the row address RA of the address ADDR to the row decoding circuit 122 and may transfer the column address CA of the address ADDR to the data input/output circuit 124. The buffer circuit 125 may exchange the data “DATA” with the data input/output circuit 124.

The control logic circuit 126 may decode the command CMD received from the buffer circuit 125 and may control the memory device 120 or various components of the memory device 120 based on a decoding result.

Under control of the control logic circuit 126, the voltage generating circuit 127 may generate various operating voltages VOP which are used in the memory device 120. In some implementations, the operating voltages VOP may include various voltages such as program voltages, pass voltages, selection read voltages, non-selection read voltages, erase voltages, verify voltages, an on-voltage, and an off-voltage. Below, various voltages which are used to describe implementation of the present disclosure may be include in the operating voltages VOP generated by the voltage generating circuit 127.

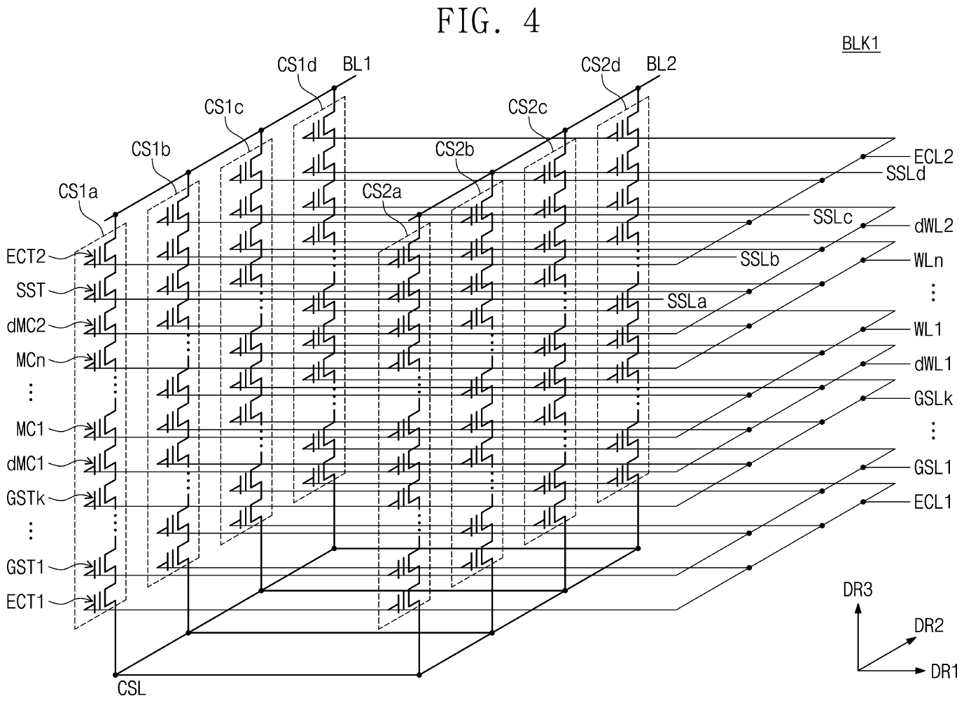

FIG. 4 is a circuit diagram illustrating an example of a first memory block included in a memory cell array 121 of FIG. 3. A structure of a first memory block BLK1 will be described with reference to FIG. 4, but the present disclosure is not limited thereto. For example, the memory cell array 121 may include a plurality of memory blocks, each of which is similar in structure to the first memory block BLK1 of FIG. 4.

In some implementations, the first memory block BLK1 to be described with reference to FIG. 4 may correspond to a physical erase unit of the memory device 120. However, the present disclosure is not limited thereto. For example, the memory device 120 may perform the erase operation in units of page, word line, sub-block, or plane.

In some implementations, the first memory block BLK1 to be described with reference to FIG. 4 is provided only as an example. The number of cell strings may increase or decrease, and the number of rows of cell strings and the number of columns of cell strings may increase or decrease depending on the number of cell strings. Also, the numbers of cell transistors GST, ECT, MC, dMC, and SST of the first memory block BLK1 may increase or decrease, and the height of the first memory block BLK1 may increase or decrease depending on the numbers of cell transistors. In addition, the number of lines GSL, WL, dWL, and SSL connected to the cell transistors may increase or decrease depending on the number of cell transistors.

Referring to FIGS. 3 and 4, the first memory block BLK1 may include the plurality of cell strings CS1a, CS1b, CS1c, CS1d, CS2a, CS2b, CS2c, and CS2d. The plurality of cell strings CS1a to CS2d may be disposed along a first direction DR1 and a second direction DR2 to form rows and columns.

The plurality cell strings CS1a to CS2d may be connected to bit lines BL1 and BL2. For example, each of the bit lines BL1 and BL2 may extend along the second direction DR2. The cell strings CS1a, CS1b, CS1c, and CS1d located at the same column, that is, the first column from among the plurality of cell strings CS1a to CS2d may be connected to the first bit line BL1, and the cell strings CS2a, CS2b, CS2c, and CS2d located at the same column, that is, the second column from among the plurality of cell strings CS1a to CS2d may be connected to the second bit line BL2.

The 1a-th cell string CS1a may include a plurality of cell transistors connected in series between the first bit line BL1 and a common source line CSL. The plurality of cell transistors of the 1a-th cell string CS1a located at the first column and first row may include a first erase control transistor ECT1, the plurality of ground selection transistors GST1 to GSTk, dummy memory cells dMC1 and dMC2, the plurality of memory cells MC1 to MCn, a string selection transistor SST, and a second erase control transistor ECT2. In some implementations, each of the plurality of cell transistors may be implemented with a charge trap flash (CTF) memory cell.

The plurality of cell transistors of the 1a-th cell string CS1a may be connected in series between the first bit line BL1 and the common source line CSL and may be stacked in a third direction DR3 (or a height direction) which is a direction perpendicular to a plane defined by the first direction DR1 and the second direction DR2 or a substrate. For example, the plurality of memory cells MC1 to MCn may be connected in series and may be stacked in the third direction DR3 (or a height direction) being a direction perpendicular to the substrate. The string selection transistor SST may be provided between the plurality of memory cells MC1 to MCn and the first bit line BL1. The plural of ground selection transistors GST1 to GSTk may be connected in series and may be stacked in the third direction DR3 (or a height direction) being a direction perpendicular to the substrate. The plurality of ground selection transistors GST1 to GSTk connected in series may be provided between the plurality of serially-connected memory cells MC1 to MCn and the common source line CSL.

In some implementations, the first dummy memory cell dMC1 may be provided between the plurality of memory cells MC1 to MCn and the plurality of ground selection transistors GST1 to GSTk. In some implementations, the second dummy memory cell dMC2 may be provided between the plurality of memory cells MC1 to MCn and the string selection transistor SST.

In some implementations, the first erase control transistor ECT1 may be provided between the plurality of ground selection transistors GST1 to GSTk and the common source line CSL. The second erase control transistor ECT2 may be provided between the string selection transistor SST and the first bit line BL1. The first and second erase control transistors ECT1 and ECT2 may be used to charge the channel of the 1a-th cell string CS1a with an erase voltage or to erase the first memory block BLK1, based on a gate induced drain leakage (GIDL) phenomenon.

For convenience of description, the structure of the 1a-th cell string CS1a is described, but the present disclosure is not limited thereto. For example, each of the remaining cell strings CS1b to CS1d and CS2a to CS2d may be similar in structure to the 1a-th cell string CS1a.

The first erase control transistors ECT1 of the plurality of cell strings CS1a to CS2d may be connected in common to a first erase control line ECL1. The second erase control transistors ECT2 of the plurality of cell strings CS1a to CS2d may be connected in common to a second erase control line ECL2.

Memory cells located at the same height from the substrate from among the plurality of memory cells MC1 to MCn may be connected in common to the same word line, and memory cells located at any other height from among the plurality of memory cells MC1 to MCn may be connected in common to any other word line. For example, the first memory cells MC1 of the plurality of cell strings CS1a to CS2d may be located at the same height from the substrate and may be connected in common to a first word line WL1. The n-th memory cells MCn of the plurality of cell strings CS1a to CS2d may be located at the same height from the substrate and may be connected in common to an n-th word line WLn.

In some implementations, the first dummy memory cells dMC1 of the plurality of cell strings CS1a to CS2d may be located at the same height from the substrate and may be connected in common to a first dummy word line dWL1. The second dummy memory cells dMC2 of the plurality of cell strings CS1a to CS2d may be located at the same height from the substrate and may be connected in common to a second dummy word line dWL2.

The string selection transistors SST of the plurality of cell strings CS1a to CS2d may be connected to a plurality of string selection lines SSLa to SSLd. For example, string selection transistors located at the same row may be connected to the same string selection line, and string selection transistors located at any other row may be connected to any other string selection line. In detail, the string selection transistors SST of the cell strings CS1a and CS2a located at the first row may be connected to an a-th string selection line SSLa; the string selection transistors SST of the cell strings CS1b and CS2b located at the second row may be connected to a b-th string selection line SSLb; the string selection transistors SST of the cell strings CS1c and CS2c located at the third row may be connected to a c-th string selection line SSLc; and, the string selection transistors SST of the cell strings CS1d and CS2d located at the fourth row may be connected to a d-th string selection line SSLd.

For brevity of drawing and for convenience of description, the description will be given as each of the plurality of cell strings CS1a to CS2d includes one string selection transistor SST, but the present disclosure is not limited thereto. Each of the plurality of cell strings CS1a to CS2d may include a plurality of string selection transistors, and string selection transistors located at the same row from among string selection transistors located at the same height from the substrate may be connected to the same string selection line; in this case, string selection transistors located at any other row may be connected to any other string selection line.

Ground selection transistors located at the same height from the substrate may be connected in common to the same ground selection line. For example, first ground selection transistors GST1 of the plurality of cell strings CS1a to CS2d may be located at the same height from the substrate and may be connected in common to a first ground selection line GSL1. k-th ground selection transistors GSTk of the plurality of cell strings CS1a to CS2d may be located at the same height from the substrate and may be connected in common to a k-th ground selection line GSLk.

As illustrated in FIG. 4, the plurality of cell strings CS1a to CS2d may be connected in common to the ground selection lines GSL1 to GSLk or may share the ground selection lines GSL1 to GSLk. In this case, as the plurality of cell strings CS1a to CS2d are controlled by the same ground selection line, a ground selection transistor of an unselected cell string may be turned on during the read operation, the verify operation, or the channel recovery operation, thereby causing issues such as the reduction of reliability, the reduction of performance, and the increase in power consumption.

To solve the above issues, the ground selection transistors GST1 to GSTk of the plurality of cell strings CS1a to CS2d may be connected to a ground selection line in units of row such that the plurality of cell strings CS1a to CS2d are controlled individually or in units of row. In this case, a ground selection transistor of an unselected cell string may be turned off during the read operation, the verify operation, or the channel recovery operation, and thus, issues such as the reduction of reliability, the reduction of performance, and the increase in power consumption may be solved.

However, the physical limitation of the first memory block BLK1 may make it difficult (or impossible) to implement a structure in which the ground selection transistors GST1 to GSTk of the plurality of cell strings CS1a to CS2d are connected to a ground selection line in units of row. In this case, the plurality of cell strings CS1a to CS2d may be individually controlled by individually setting a threshold voltage of each of the ground selection transistors GST1 to GSTk of the plurality of cell strings CS1a to CS2d and controlling voltages of the plurality of ground selection lines GSL1 to GSLk. In the present disclosure, the above structure is called the coded GSL structure.

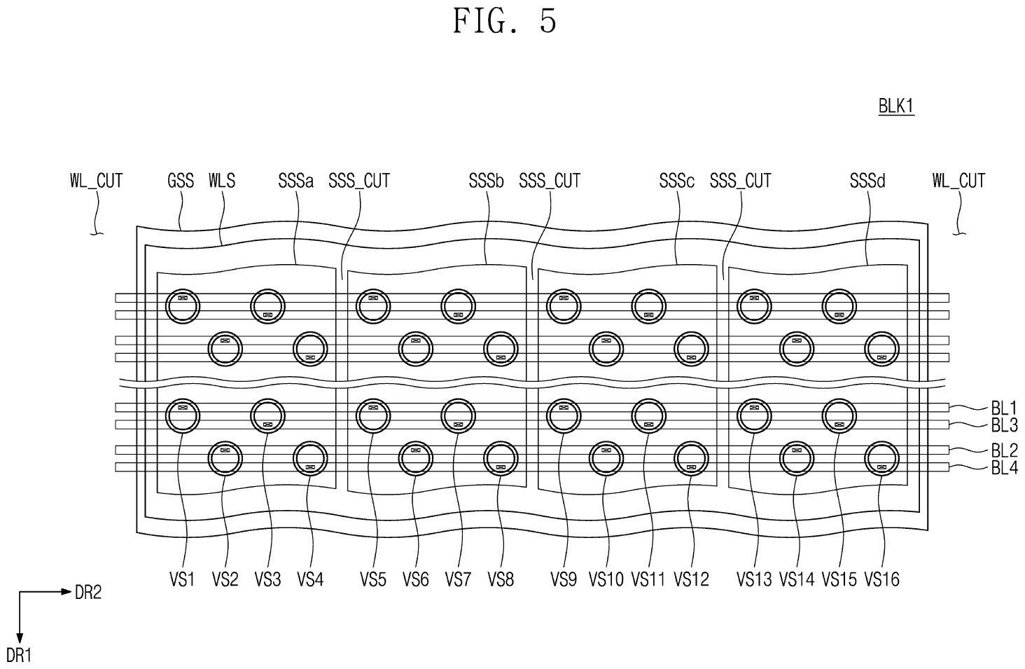

FIG. 5 is a plan view of an example of a first memory block of FIG. 4. In FIG. 5, some components of the first memory block BLK1 are omitted. However, the present disclosure is not limited thereto. Referring to FIGS. 4 and 5, the first memory block BLK1 may be formed on the substrate. The first memory block BLK1 may include a ground selection structure GSS, a word line structure WLS, and a plurality of string selection structures SSSa, SSSb, SSSc, and SSSd. The ground selection structure GSS, the word line structure WLS, and the plurality of string selection structures SSSa, SSSb, SSSc, and SSSd may be provided between word line cuts WL_CUT and may be stacked along a direction (e.g., the third direction DR3) perpendicular to the substrate defined by the first direction DR1 and the second direction DR2.

The plurality of string selection structures SSSa, SSSb, SSSc, and SSSd may extend along the first direction DR1 and may be electrically separated from each other by string selection cuts SSS_CUT. The first memory block BLK1 may include a plurality of vertical structures VS1 to VS16. The plurality of vertical structures VS1 to VS16 may penetrate the ground selection structure GSS, the word line structure WLS, and the plurality of string selection structures SSSa, SSSb, SSSc, and SSSd. For example, the first to fourth vertical structures VS1 to VS4 may penetrate the ground selection structure GSS, the word line structure WLS, and the a-th string selection structure SSSa; the fifth to eighth vertical structures VS5 to VS8 may penetrate the ground selection structure GSS, the word line structure WLS, and the b-th string selection structure SSSb; the ninth to twelfth vertical structures VS9 to VS12 may penetrate the ground selection structure GSS, the word line structure WLS, and the c-th string selection structure SSSc; and, the thirteenth to sixteenth vertical structures VS13 to VS16 may penetrate the ground selection structure GSS, the word line structure WLS, and the d-th string selection structure SSSd.

The plurality of vertical structures VS1 to VS16 may be connected to a plurality of bit lines BL1, BL2, BL3, and BL4 extending along the second direction DR2. For example, the first, fifth, ninth, and thirteenth vertical structures VS1, VS5, VS9, and VS13 may be connected to the first bit line BL1; the second, sixth, tenth, and fourteenth vertical structures VS2, VS6, VS10, and VS14 may be connected to the second bit line BL2, the third, seventh, eleventh, and fifteenth vertical structures VS3, VS7, VS11, and VS15 may be connected to the third bit line BL3, and the fourth, eighth, twelfth, and sixteenth vertical structures VS4, VS8, VS12, and VS16 may be connected to the fourth bit line BL4.

In some implementations, each of the plurality of vertical structures VS1 to VS16 may form a cell string. For example, the first and second vertical structures VS1 and VS2 of FIG. 5 may respectively correspond to the 1a-th and 2a-th cell strings CS1a and CS2a of FIG. 4; the fifth and sixth vertical structures VS5 and VS6 of FIG. 5 may respectively correspond to the 1b-th and 2b-th cell strings CS1b and CS2b of FIG. 4; the ninth and tenth vertical structures VS9 and VS10 of FIG. 5 may respectively correspond to the 1c-th and 2c-th cell strings CS1c and CS2c of FIG. 4; and, the thirteenth and fourteenth vertical structures VS13 and VS14 of FIG. 5 may respectively correspond to the 1d-th and 2d-th cell strings CS1d and CS2d of FIG. 4.

In the structure of the first memory block BLK1 described with reference to FIG. 5, four string selection structures SSSa to SSSd may respectively correspond to the four string selection lines SSLa to SSLd of FIG. 4. That is, in the first memory block BLK1 described with reference to FIG. 4, cell strings connected to the four string selection lines SSLa to SSLd may share ground selection lines.

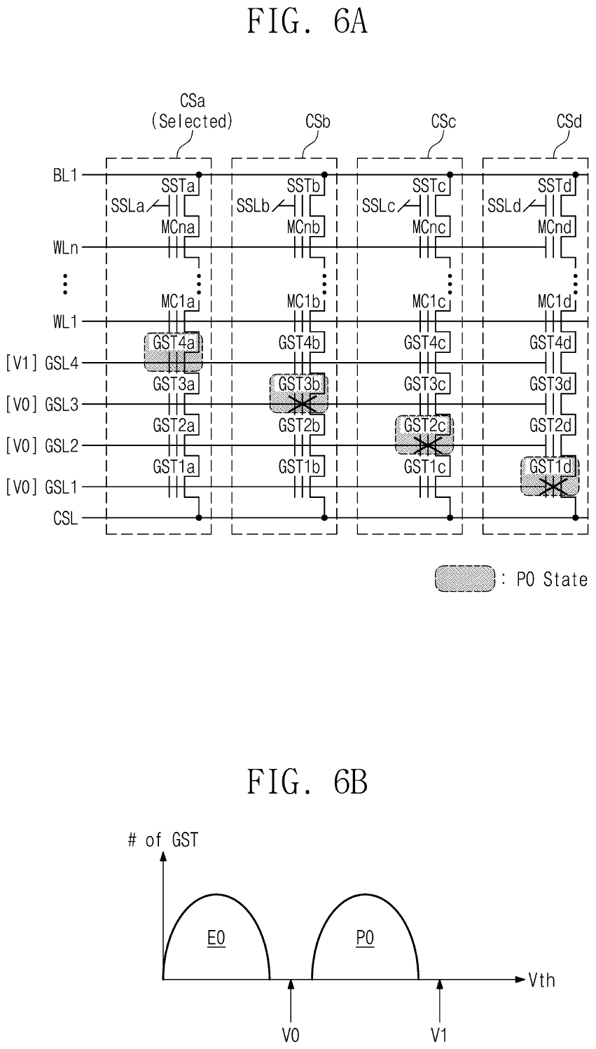

FIGS. 6A and 6B are diagrams for describing an example of a method of controlling a first memory block of FIGS. 4 and 5. Below, for convenience of description, implementations of the present disclosure will be described based on the plurality of cell strings CSa, CSb, CSc, and CSd connected to the first bit line BL1. Also, some (e.g., dummy memory cells and erase control transistors) of cell transistors included in each of the plurality of cell strings CSa, CSb, CSc, and CSd are omitted. However, the present disclosure is not limited thereto.

Below, for brevity of drawing and for convenience of description, some ground selection lines GSL and some ground selection transistors GST are illustrated in a drawing, but the present disclosure is not limited thereto. For example, in the following drawings, ground selection transistors are illustrated as being directly connected to the common source line CSL, but additional ground selection transistors may further exist between the illustrated ground selection transistors or the dummy ground selection transistors and the common source line CSL.

Referring to FIGS. 4 to 6B, the first memory block BLK1 may include the a-th to d-th cell strings CSa to CSd. Each of the a-th to d-th cell strings CSa to CSd may be connected between the first bit line BL1 and the common source line CSL. The a-th cell string CSa may include a plurality of ground selection transistors GST1a to GST4a, a plurality of memory cells MC1a to MCna, and an a-th string selection transistor SSTa. The b-th cell string CSb may include a plurality of ground selection transistors GST1b to GST4b, a plurality of memory cells MC1b to MCnb, and a b-th string selection transistor SSTb. The c-th cell string CSc may include a plurality of ground selection transistors GST1c to GST4c, a plurality of memory cells MC1c to MCnc, and a c-th string selection transistor SSTc. The d-th cell string CSd may include a plurality of ground selection transistors GST1d to GST4d, a plurality of memory cells MC1d to MCnd, and a d-th string selection transistor SSTd.

The string selection transistors SSTa of the a-th cell string CSa may be connected to the a-th string selection line SSLa; the string selection transistors SSTb of the b-th cell string CSb may be connected to the b-th string selection line SSLb; the string selection transistors SSTc of the c-th cell string CSc may be connected to the c-th string selection line SSLc; and, the string selection transistors SSTd of the d-th cell string CSd may be connected to the d-th string selection line SSLd.

The ground selection transistors GST1a to GST4a, GST1b to GST4b, GST1c to GST4c, and GST1d to GST4d and the memory cells MC1a to MCna, MC1b to MCnb, MC1c to MCnc, and MC1d to MCnd of the a-th to d-th cell strings CSa to CSd may be connected to the plurality of ground selection lines GSL1 to GSL4 and the plurality of word lines WL1 to WLn. For example, the first memory cells MC1a, MC1b, MC1c, and MC1d of the a-th to d-th cell strings CSa to CSd may be connected to the first word line WL1, and the n-th memory cells MCna, MCnb, MCnc, and MCnd of the a-th to d-th cell strings CSa to CSd may be connected to the n-th word line WLn.

The ground selection transistors GST1a, GST1b, GST1c, and GST1d of the a-th to d-th cell strings CSa to CSd may be connected to the first ground selection line GSL1; the ground selection transistors GST2a, GST2b, GST2c, and GST2d of the a-th to d-th cell strings CSa to CSd may be connected to the second ground selection line GSL2; the ground selection transistors GST3a, GST3b, GST3c, and GST3d of the a-th to d-th cell strings CSa to CSd may be connected to the third ground selection line GSL3; and, the ground selection transistors GST4a, GST4b, GST4c, and GST4d of the a-th to d-th cell strings CSa to CSd may be connected to the fourth ground selection line GSL4.

In some implementations, while the memory device 120 operates, one of the plurality of cell strings CSa to CSd may be selected, and the remaining cell strings may not be selected. In this case, a threshold voltage (Vth) of each of the plurality of ground selection transistors GST1a to GST4d may be set such that the remaining unselected cell strings among the plurality of cell strings CSa to CSd other than the selected cell string are not electrically connected to the common source line CSL.

For example, as illustrated in FIG. 6B, a threshold voltage or a threshold voltage distribution of a 0-th program state P0 may be higher than a threshold voltage or a threshold voltage distribution of a 0-th erase state E0. In this case, a ground selection transistor having the 0-th program state P0 may be turned off by a 0-th voltage V0 and may be turned on by a first voltage V1. Also, a ground selection transistor with the 0-th erase state E0 may be turned on by the 0-th voltage V0 and may be turned on by the first voltage V1.

The threshold voltages of 4a-th, 3b-th, 2c-th, and 1d-th ground selection transistors GST4a, GST3b, GST2c, and GST1d among the plurality of ground selection transistors GST1a to GST4a may be set to the 0-th program state P0. In this case, as the 0-th voltage V0 or the first voltage V1 is applied to each of the plurality of ground selection lines GSL1 to GSL4, the remaining unselected cell strings among the plurality of cell strings CSa to CSd other than the selected cell string may not be electrically connected to the common source line CSL.

In detail, it is assumed that the a-th cell string CSa is a selected cell string. In this case, the 0-th voltage V0 may be applied to the first to third ground selection line lines GSL1 to GSL3, and the first voltage V1 may be applied to the fourth ground selection lines GSL4 (i.e., set bias conditions or voltage levels corresponding to the ground selection lines GSL1 to GSL4). As the 0-th voltage V0 is applied to the first ground selection line GSL1, the 1a-th, 1b-th, and 1c-th ground selection transistors GST1a, GST1b, and GST1c may be turned on, and the 1d-th ground selection transistor GST1d may be turned off. As the 0-th voltage V0 is applied to the second ground selection line GSL2, the 2a-th, 2b-th, and 2d-th ground selection transistors GST2a, GST2b, and GST2d may be turned on, and the 2c-th ground selection transistor GST2c may be turned off. As the 0-th voltage V0 is applied to the third ground selection line GSL3, the 3a-th, 3c-th, and 3d-th ground selection transistors GST3a, GST3c, and GST3d may be turned on, and the 3b-th ground selection transistor GST3b may be turned off. As the first voltage V1 is applied to the fourth ground selection line GSL4, the ground selection transistors GST4a, GST4b, GST4c, and GST4d connected to the fourth ground selection line GSL4 may be turned on.

That is, according to the above bias condition associated with the ground selection lines GSL1 to GSL4, because all the ground selection transistors GST1a to GST4a of the a-th cell string CSa being the selected cell string are turned on, the a-th cell string CSa may be electrically connected to the common source line CSL. In contrast, because the 3b-th, 2c-th, and 1d-th ground selection transistors GST3b, GST2c, and GST1d are turned off, the b-th, c-th, and d-th cell strings CSb, CSc, and CSd being the unselected cell strings may be electrically separated from the common source line CSL. Accordingly, issues, which may occur during the operation of the memory device 120, such as the reduction of reliability, the reduction of performance, and the increase in power consumption may be prevented.

In some implementations, the threshold voltage distribution of the 0-th erase state E0 may be different from the threshold voltage distribution of the 0-th program state P0. In some implementations, the threshold voltage distribution of the 0-th erase state E0 may be lower than the threshold voltage distribution of the 0-th program state P0. For example, threshold voltages of ground selection transistors corresponding to the 0-th erase state E0 may be lower than threshold voltages of ground selection transistors corresponding to the 0-th program state P0. In some implementations, the threshold voltages of the ground selection transistors corresponding to the 0-th erase state E0 may be identical to or different from threshold voltages of memory cells MC corresponding to an erase state “E”.

In some implementations, the program operation for the ground selection lines GSL1 to GSL4 may be performed to set the ground selection transistors GST4a, GST3b, GST2c, and GST1d to the threshold voltage of the 0-th program state P0. For example, the threshold voltage of the 4a-th ground selection transistor GST4a may be set to the 0-th program state P0 by applying the program voltage to the fourth ground selection line GSL4 and applying the pass voltage to the remaining lines (e.g., GSL1 to GSL3 and WL1 to WLn). The threshold voltage of the 3b-th ground selection transistor GST3b may be set to the 0-th program state P0 by applying the program voltage to the third ground selection line GSL3 and applying the pass voltage to the remaining lines (e.g., GSL1, GSL2, GSL4, and WL1 to WLn). The threshold voltage of the 2c-th ground selection transistor GST2c may be set to the 0-th program state P0 by applying the program voltage to the second ground selection line GSL2 and applying the pass voltage to the remaining lines (e.g., GSL1, GSL3, GSL4, and WL1 to WLn). The threshold voltage of the 1d-th ground selection transistor GST1d may be set to the 0-th program state P0 by applying the program voltage to the first ground selection line GSL1 and applying the pass voltage to the remaining lines (e.g., GSL2, GSL3, GSL4, and WL1 to WLn).

In some implementations, the threshold voltages of the ground selection transistors GST1a to GST4d may be changed due to various factors. For example, as the memory device 120 operates, the threshold voltages of the ground selection transistors GST1a to GST4d may decrease depending on a retention characteristic of the ground selection transistors GST1a to GST4d. Alternatively, as the memory device 120 operates, the read disturbance may occur in the ground selection transistors GST1a to GST4d, thereby causing the increase in the threshold voltages of the ground selection transistors GST1a to GST4d. Alternatively, as the memory device 120 operates, a hot electron injection phenomenon may occur in the ground selection transistors GST1a to GST4d, thereby causing the increase in the threshold voltages of the ground selection transistors GST1a to GST4d. As described above, as the threshold voltages of the ground selection transistors GST1a to GST4d are changed, the memory device 120 may not operate normally; in this case, data stored in memory cells may not be normally read.

According to some implementations of the present disclosure, the GSL coding pattern of the memory device 120 may be changed depending on various conditions. In this case, the degradation or error for the coded GSL coding pattern of the memory device 120 may decrease.

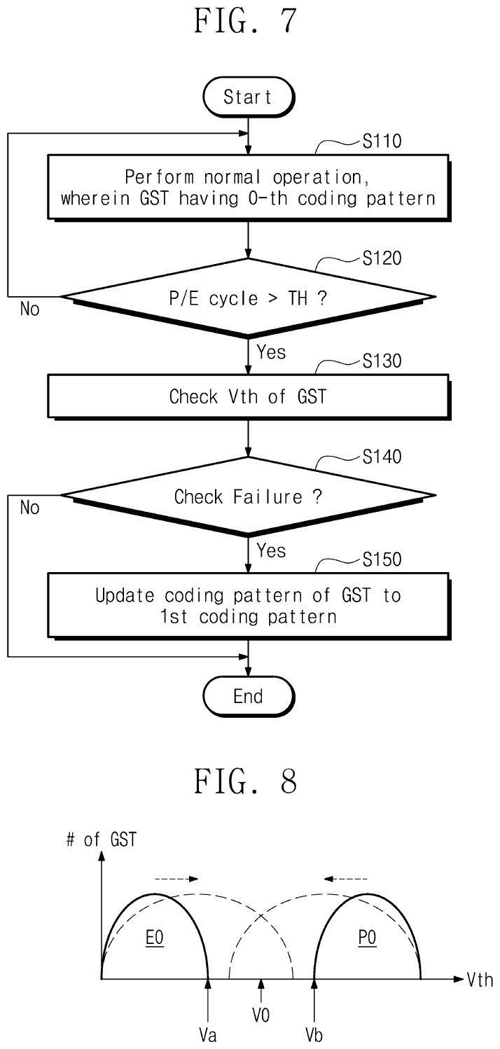

FIG. 7 is a flowchart illustrating an example of an operation of a memory device of FIG. 1. FIG. 8 is a diagram for describing an example operation S130 of FIG. 7. Below, for convenience, an implementation of changing the GSL coding pattern of the first memory block BLK1 will be described. However, the present disclosure is not limited thereto. For example, the storage device 100 may change the GSL coding pattern for each of a plurality of memory blocks.

Referring to FIGS. 1 and 6A to 8, in operation S110, the memory device 120 may perform a normal operation. For example, the memory device 120 may perform the program operation, the read operation, or the erase operation under control of the controller 110. In some implementations, the ground selection transistors of each of the plurality of memory blocks of the memory device 120 may have the 0-th GSL coding pattern. The 0-th GSL coding pattern will be described in detail with reference to the following drawings.

In operation S120, the memory device 120 may determine whether a program and erase cycle count (hereinafter referred to as a “P/E cycle”) of the memory device 120 is greater than a reference value TH. In some implementations, operation S120 may be performed by the controller 110 configured to control the memory device 120. For example, the controller 110 may manage the P/E cycle of the first memory block BLK1 of the memory device 120. The controller 110 may determine whether the P/E cycle of the first memory block BLK1 is greater than the reference value TH. When the P/E cycle of the first memory block BLK1 is not greater than the reference value TH, the memory device 120 may continuously perform operation S110.

When the P/E cycle of the first memory block BLK1 is greater than the reference value TH, in operation S130, the memory device 120 may check threshold voltages Vth of the ground selection transistors of the first memory block BLK1. For example, as described with reference to FIGS. 6A and 6B, the ground selection transistors GST of the first memory block BLK1 may have the 0-th erase state E0 or the 0-th program state P0. In this case, due to various factors, the threshold voltages of the ground selection transistors GST of the first memory block BLK1 may change. As an example, as illustrated in FIG. 8, the threshold voltages of the ground selection transistors GST of the 0-th erase state E0 may be higher than an upper limit value or upper limit level (e.g., Va) of the 0-th erase state E0, or the threshold voltages of the ground selection transistors GST of the 0-th program state P0 may be lower than a lower limit value or lower limit level (e.g., Vb) of the 0-th program state P0. In this case, the ground selection transistors GST may not be normally controlled. For example, the ground selection transistors of the 0-th erase state E0 should be turned on by the 0-th voltage V0; however, as the threshold voltages of the ground selection transistors of the 0-th erase state E0 increase, the ground selection transistors of the 0-th erase state E0 may not be normally turned on. Alternatively, the ground selection transistors of the 0-th program state P0 should be turned off by the 0-th voltage V0; however, as the threshold voltages of the ground selection transistors of the 0-th program state P0 decrease, the ground selection transistors of the 0-th program state P0 may not be normally turned off.

In some implementations, the operation of checking the threshold voltages of the ground selection transistors GST of the first memory block BLK1 (or referred to as a check operation) may indicate an operation of counting the number of ground selection transistors having a threshold voltage higher than the Va from among the ground selection transistors of the 0-th erase state E0 or the number of ground selection transistors having a threshold voltage lower than the Vb from among the ground selection transistors of the 0-th program state P0.

In operation S140, the memory device 120 may determine whether the check operation is failed. For example, when the number of ground selection transistors having a threshold voltage higher than the Va from among the ground selection transistors of the 0-th erase state E0 or the number of ground selection transistors having a threshold voltage lower than the Vb from among the ground selection transistors of the 0-th program state P0 is more than a reference value, the check operation may be determined as being failed. In some implementations, operation S140 may be performed by the controller 110 configured to control the memory device 120.

When the check operation is failed, in operation S150, the memory device 120 may change the GSL coding pattern of the ground selection transistors of the first memory block BLK1 to a first GSL coding pattern different from the 0-th GSL coding pattern (or the memory device 120 may update the GSL coding pattern of the ground selection transistors of the first memory block BLK1 so as to be changed to a first GSL coding pattern different from the 0-th GSL coding pattern). For example, the memory device 120 may perform the program operation for the ground selection transistors GST of the first memory block BLK1 without the erase operation for the first memory block BLK1, and thus, the GSL coding pattern of the ground selection transistors GST of the first memory block BLK1 is changed to the first GSL coding pattern.

Alternatively, the memory device 120 may perform the erase operation for the ground selection transistors GST of the first memory block BLK1 and may perform the program operation for the first memory block BLK1, and thus, the GSL coding pattern of the ground selection transistors GST of the first memory block BLK1 may be changed to the first GSL coding pattern. Various implementations of the 0-th and first GSL coding patterns may be described in detail with reference to the following drawings.

In some implementations, the 0-th GSL coding pattern and the first GSL coding pattern may be different from each other. When the ground selection transistors of the first memory block BLK1 have the 0-th GSL coding pattern, the memory device 120 may control the first memory block BLK1 based on a 0-th bias condition. When the ground selection transistors of the first memory block BLK1 have the first GSL coding pattern, the memory device 120 may control the first memory block BLK1 based on a first bias condition different form the 0-th bias condition.

As described above, according to some implementations of the present disclosure, the memory device 120 may change the GSL coding pattern of memory blocks of the memory device 120 when a specific condition is satisfied. Accordingly, the reliability and performance of the memory device 120 may be improved. In some implementations, the operation of changing or updating the GSL coding pattern may be performed under control of the controller 110 or the GSL managing circuit 111 of the controller 110.

In some implementations, a configuration for performing the operation of updating the GSL coding pattern when the check operation is failed is described, but the present disclosure is not limited thereto. For example, when the P/E cycle of the first memory block BLK1 reaches the reference value, the memory device 120 may change or update the GSL coding pattern of the first memory block BLK1. Alternatively, when the P/E cycle of the first memory block BLK1 reaches the reference value, the memory device 120 may control the threshold voltages of each of the plurality of ground selection transistors GST included in the cell strings of the first memory block BLK1. Alternatively, even though the P/E cycle of the first memory block BLK1 does not reach the reference value, when the check operation is failed, the memory device 120 may change or update the GSL coding pattern of the first memory block BLK1.

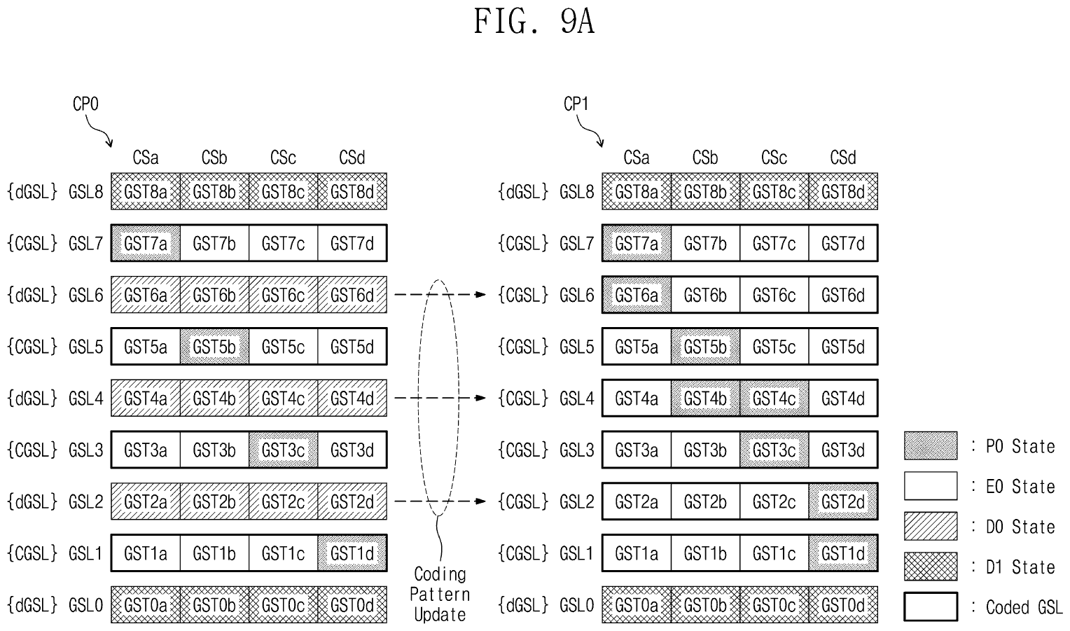

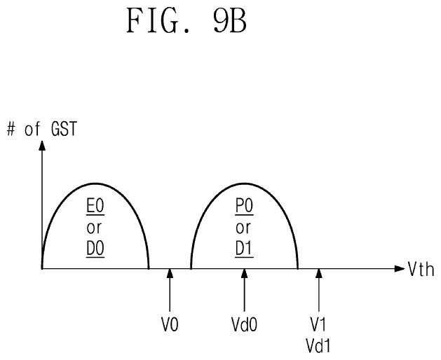

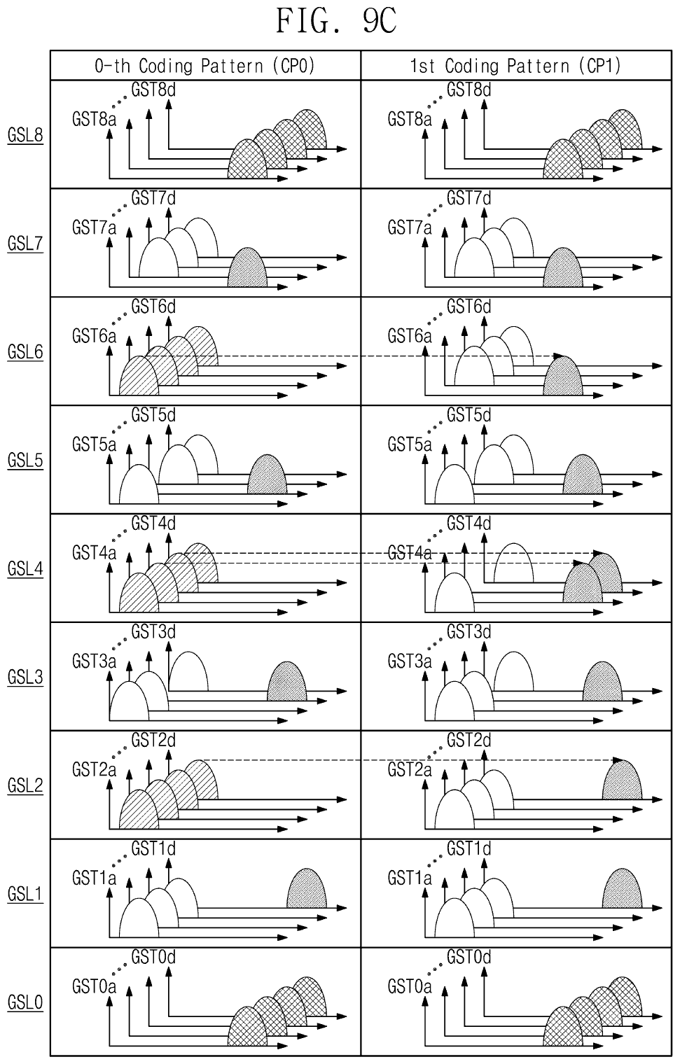

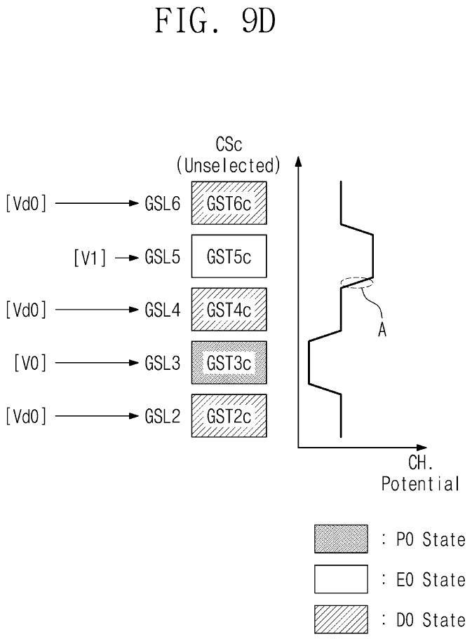

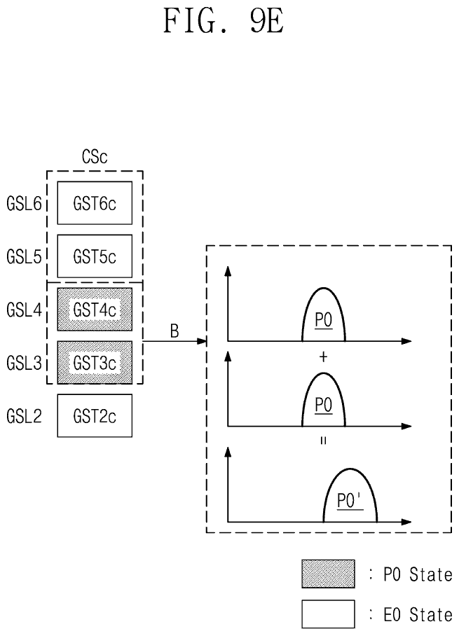

FIGS. 9A, 9B, 9C, 9D, and 9E are diagrams for describing an example of a GSL coding pattern change operation in operation S150 of FIG. 7. Below, for brevity of drawing, the GSL coding pattern corresponding to the ground selection transistors of the first memory block BLK1 is illustrated. However, the present disclosure is not limited thereto. For example, it may be understood that the ground selection transistors of the memory device 120 have threshold voltages corresponding to a GSL coding pattern to be described with reference to the following drawings and that the ground selection transistors are applicable to the first memory block BLK1 or the memory device 120 described above.

First, referring to FIGS. 1, 9A, and 9B, the first memory block BLK1 may include the a-th to d-th cell strings CSa to CSd. The a-th cell string CSa may include a plurality of ground selection transistors GST0a to GST8a, the b-th cell string CSb may include a plurality of ground selection transistors GST0b to GST8b, the c-th cell string CSc may include a plurality of ground selection transistors GST0c to GST8c, and the d-th cell string CSd may include a plurality of ground selection transistors GST0d to GST8d. The ground selection transistors GST0a to GST8d of the a-th to d-th cell strings CSa to CSd may be respectively connected to 0-th to eighth ground selection lines GSL0 to GSL8.

In some implementations, as described above, each of the plurality of cell strings CSa to CSd may further include at least one string selection transistor SST, a plurality of memory cells MC, at least one dummy memory cell dMC, and at least one erase control transistor ECT.

First, the first memory block BLK1 may have a 0-th GSL coding pattern CP0. In this case, the first, third, fifth, and seventh ground selection lines GSL1, GSL3, GSL5, and GSL7 may be used as a coding ground selection line CGSL, and the remaining ground selection lines GSL0, GSL2, GSL4, GSL6, and GSL8 may be used as a dummy ground selection line dGSL.

In some implementations, the coding ground selection line CGSL may indicate a ground selection line to which a voltage varying depending on a selected cell string is applied, and the dummy ground selection line dGSL may indicate a ground selection line to which a uniform voltage is applied regardless of a selected cell string. Alternatively, the ground selection transistors connected to the coding ground selection line CGSL may have different threshold voltage states (e.g., E0 and P0), and the ground selection transistors connected to the dummy ground selection line dGSL may have the same threshold voltage state (e.g., D0 or D1).

In detail, when the first memory block BLK1 has the 0-th GSL coding pattern CP0, the ground selection transistors GST0a to GST0d and GST8a to GST8d connected to the 0-th and eighth ground selection lines GSL0 and GSL8 being the dummy ground selection lines dGSL may have a first dummy state D1. The ground selection transistors GST2a to GST2d, GST4a to GST4d, and GST6a to GST6d respectively connected to the second, fourth, and sixth ground selection lines GSL2, GSL4, and GSL6 being the dummy ground selection line dGSL may have a 0-th dummy state D0.

Some ground selection transistors GST1d, GST3c, GST5b, and GST7a among the ground selection transistors GST1a to GST1d, GST3a to GST3d, GST5a to GST5d, and GST7a to GST7d respectively connected to the first, third, fifth, and seventh ground selection lines GSL1, GSL3, GSL5, and GSL7 being the coding ground selection line CGSL may have the 0-th program state P0, and the others thereof may have the 0-th erase state E0.

In some implementations, as illustrated in FIG. 9B, the 0-th dummy state D0 may be a threshold voltage state the same as the 0-th erase state E0, and the first dummy state D1 may be a threshold voltage state the same as the 0-th program state P0. However, the present disclosure is not limited thereto. For example, the threshold voltage states may be different from each other.

In this case, during the operation for the first memory block BLK1, a first dummy voltage Vd1 may be applied to the 0-th and eighth ground selection lines GSL0 and GSL8, a 0-th dummy voltage Vd0 may be applied to the second, fourth, and sixth ground selection lines GSL2, GSL4, and GSL6, and the 0-th voltage V0 or the first voltage V1 may be applied to each of the first, third, fifth, and seventh ground selection lines GSL1, GSL3, GSL5, and GSL7 depending on a selected cell string.

As described above, when the first memory block BLK1 has the 0-th GSL coding pattern CP0, some (e.g., GSL0, GSL2, GSL4, GSL6, and GSL8) of the plurality of ground selection lines GSL0 to GSL8 may be used as the dummy ground selection line dGSL, and the others (e.g., GSL1, GSL3, GSL5, and GSL7) thereof may be used as the coding ground selection line CGSL.

In some implementations, while the memory device 120 is operating, a specific condition (e.g., the condition that the P/E cycle is greater than the reference value TH and the check operation is failed) may be satisfied. In this case, under control of the controller 110, the memory device 120 may change or update the GSL coding pattern from the 0-th GSL coding pattern CP0 to a first GSL coding pattern CP1.

For example, in the first GSL coding pattern CP1, the first to seventh ground selection lines GSL1 to GSL7 are used as the coding ground selection line CGSL. In this case, some ground selection transistors GST1d, GST2d, GST3c, GST4c, GST4b, GST5b, GST6a, and GST7a among the ground selection transistors connected to the first to seventh ground selection lines GSL1 to GSL7 may have the 0-th program state P0, and the others thereof have the 0-th erase state E0.

As described above, the memory device 120 may change or update the GSL coding pattern of the first memory block BLK1 from the 0-th GSL coding pattern CP0 to the first GSL coding pattern CP1. In some implementations, the change or update from the 0-th GSL coding pattern CP0 to the first GSL coding pattern CP1 may be performed through the program operation for the dummy ground selection line dGSL without the erase operation for the first memory block BLK1 (i.e., maintain the first memory block BLK1).

For example, as illustrated in FIG. 9C, in the 0-th GSL coding pattern CP0, the ground selection transistors GST2a to GST2d, GST4a to GST4d, and GST6a to GST6d connected to the second, fourth, and sixth ground selection lines GSL2, GSL4, and GSL6 may have the 0-th dummy state DO. In this case, the memory device 120 may program the 2d-th ground selection transistor GST2d to the 0-th program state P0 by performing the program operation for the second ground selection line GSL2, may program the 4b-th and 4c-th ground selection transistors GST4b and GST4c to the 0-th program state P0 by performing the program operation for the fourth ground selection line GSL4, and may program the 6a-th ground selection transistor GST6a to the 0-th program state P0 by performing the program operation for the sixth ground selection line GSL6. Accordingly, the ground selection transistors GST1a to GST7d connected to the first to seventh ground selection lines GSL1 to GSL7 may have the first GSL coding pattern CP1.

As described above, in the 0-th GSL coding pattern CP0, the dummy ground selection lines dGSL may be placed between the coding ground selection lines CGSL. The memory device 120 may perform the program operation for the dummy ground selection lines dGSL such that the GSL coding pattern for the ground selection transistors GST is changed or updated to the first GSL coding pattern CP1.

In some implementations, the 0-th GSL coding pattern CP0 may be relatively robust for the hot electron injection. For example, as illustrated in FIG. 9D, in the 0-th GSL coding pattern CP0, it is assumed that the c-th cell string CSc is an unselected cell string. In this case, the 0-th dummy voltage Vd0 may be applied to the second, fourth, and sixth ground selection lines GSL2, GSL4, and GSL6 being the dummy ground selection line dGSL, the 0-th voltage V0 may be applied to the third ground selection line GSL3 being the coding ground selection line CGSL, and the first voltage V1 may be applied to the fifth ground selection line GSL5 being the coding ground selection line CGSL.

According to the above bias condition, a channel potential difference may occur depending on the voltages Vd0, V0, and V1 applied to the ground selection lines GSL2 to GSL6 and threshold voltage states of the ground selection transistors GST2c to GST6c. As the channel potential difference increases, the effect of the hot electron injection may increase, which causes the increase in threshold voltages of ground selection transistors.

However, as illustrated in FIG. 9D, as the fourth ground selection line GSL4 is used as the dummy ground selection line dGSL, the channel potential difference occurring at one end “A” of the 5c-th ground selection transistor GST5c may decrease, and thus, the hot electron injection may decrease. That is, in the 0-th GSL coding pattern CP0, as the dummy ground selection lines dGSL are disposed between the coding ground selection lines CGSL, the increase in threshold voltages of ground selection transistors due to the hot electron injection (HCI) may be prevented.

In some implementations, the first GSL coding pattern CP1 may be relatively robust for the retention characteristic. For example, in each cell string, at least two adjacent ground selection transistors may have the same threshold voltage state. In this case, because an appearance threshold voltage state for at least two adjacent ground selection transistors is relatively high, the first GSL coding pattern CP1 may be relatively robust for the retention characteristic.

In detail, as illustrated in FIG. 9E, in the c-th cell string CSc, the 5c-th and 6c-th ground selection transistors GST5c and GST6c adjacent to each other may have the same 0-th erase state E0. In the c-th cell string CSc, the 3c-th and 4c-th ground selection transistors GST3c and GST4c adjacent to each other may have the same 0-th program state P0. In this case, when each of the 3c-th and 4c-th ground selection transistors GST3c and GST4c has the 0-th program state P0 but the 3c-th and 4c-th ground selection transistors GST3c and GST4c are controlled by the same bias (i.e., when the 3c-th and 4c-th ground selection transistors GST3c and GST4c are equalized to one transistor as marked by “B”), the appearance threshold voltage state of the 3c-th and 4c-th ground selection transistors GST3c and GST4c may increase like P0′. Accordingly, due to the retention characteristic, even though the threshold voltage of each of the 3c-th and 4c-th ground selection transistors GST3c and GST4c decreases, the change in the threshold voltage state for all the 3c-th and 4c-th ground selection transistors GST3c and GST4c may be slight. This means that the ground selection transistor is relatively robust for the retention characteristic.

As described above, when the specific condition is satisfied, the memory device 120 may change the 0-th GSL coding pattern CP0 of the first memory block BLK1 to the first GSL coding pattern CP1. In this case, in the early part of the lifetime of the memory device 120, in which the memory device 120 is relatively vulnerable to the hot electron injection (HCI), because the first memory block BLK1 has the 0-th GSL coding pattern robust for the hot electron injection, the change in threshold voltages of ground selection transistors may decrease. In this case, in the latter part of the lifetime of the memory device 120, in which the memory device 120 is relatively vulnerable to the retention characteristic, because the first memory block BLK1 has the first GSL coding pattern CP1 robust for the retention characteristic, the change in threshold voltages of ground selection transistors may decrease. Accordingly, the reliability of the memory device 120 may be improved.

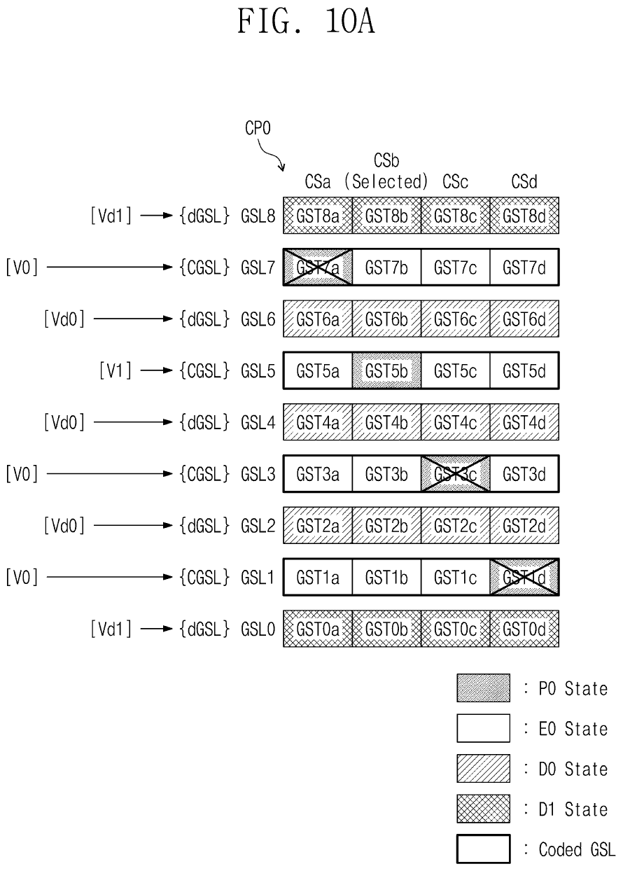

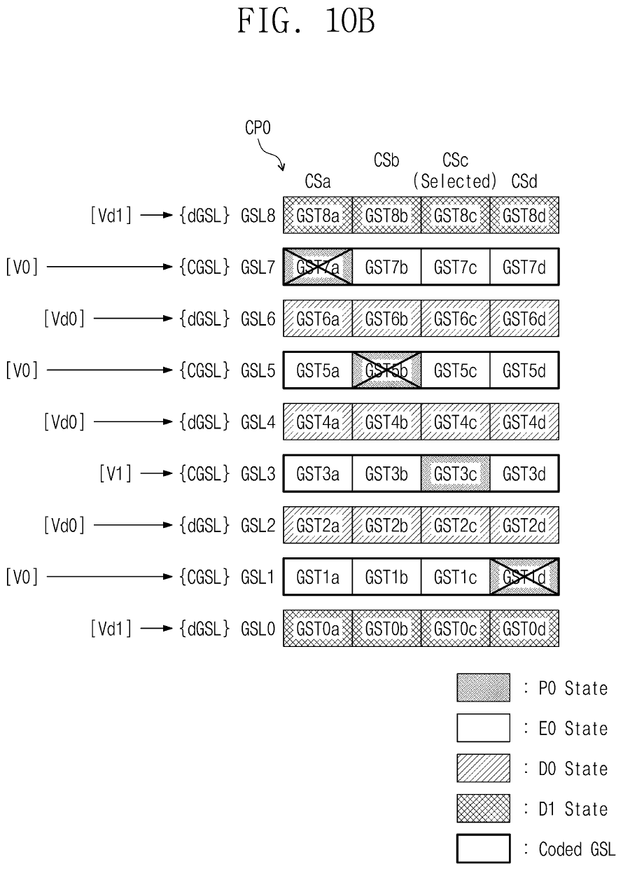

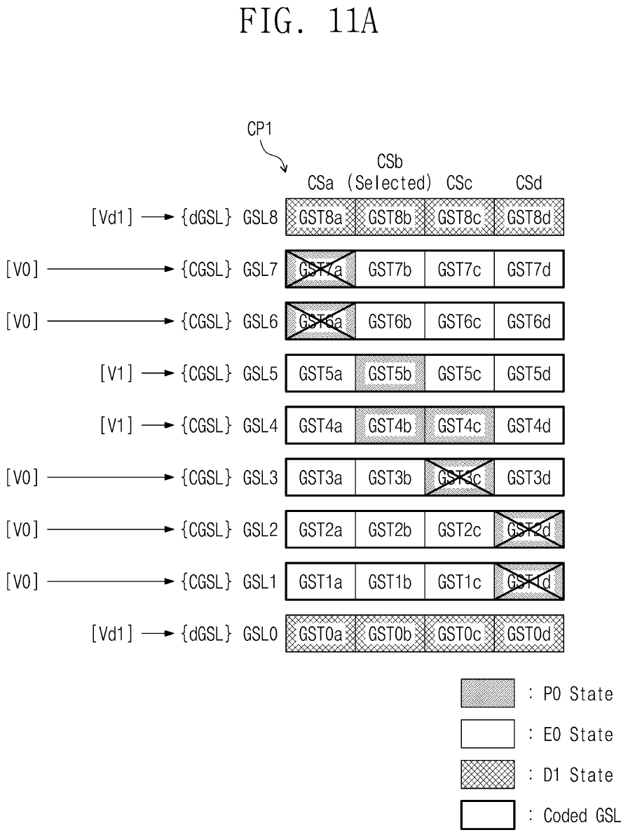

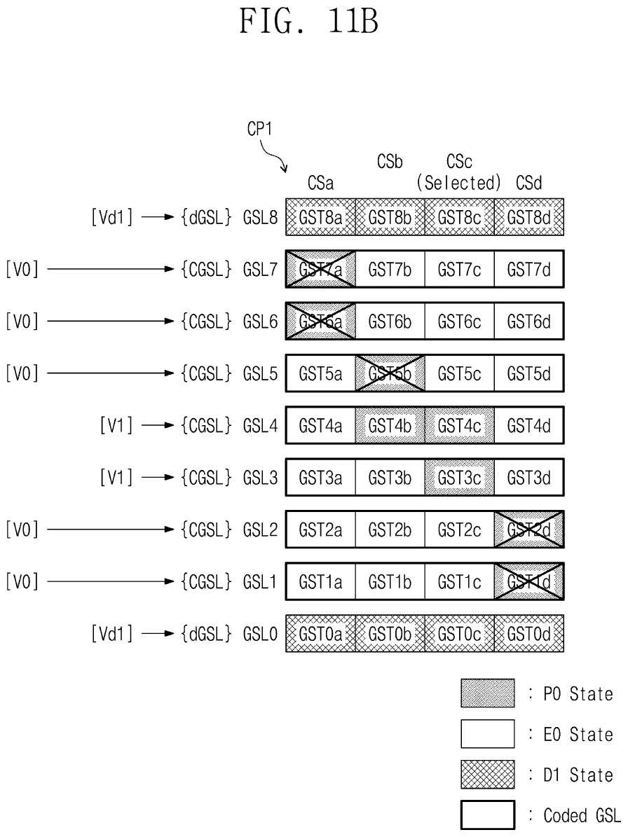

FIGS. 10A and 10B are diagrams for describing an example of a bias condition for a first memory block having a 0-th GSL coding pattern. FIGS. 11A and 11B are diagrams for describing an example of a bias condition for a first memory block having a first GSL coding pattern.

First, referring to FIGS. 1, 10A, and 10B, the first memory block BLK1 of the memory device 120 may have the 0-th GSL coding pattern CP0. For example, because the 0-th GSL coding pattern CP0 of the first memory block BLK1 is described with reference to FIG. 9A, additional description will be omitted to avoid redundancy.

Below, the description will be given as the 0-th voltage V0, the first voltage V1, the 0-th dummy voltage Vd0, and the first dummy voltage Vd1 are applied to the ground selection lines GSL to perform various operations (e.g., the read operation, the program operation, and the verify operation) for the first memory block BLK1. In this case, ground selection transistors of the 0-th erase state E0 or the 0-th dummy state DO may be turned on by the 0-th dummy voltage Vd0 or the 0-th voltage V0, and ground selection transistors of the 0-th program state P0 or the first dummy state D1 may be turned off by the 0-th voltage V0. Ground selection transistors of the 0-th erase state E0, the 0-th dummy state D0, the 0-th program state P0, or the first dummy state D1 may be turned on by the first dummy voltage Vd1 or the first voltage V1.

First, in FIG. 10A, it is assumed that the b-th cell string CSb is a selected cell string. In this case, various voltages may be applied to the 0-th to eighth ground selection lines GSL0 to GSL8 such that all the ground selection transistors GST0b to GST8b of the b-th cell string CSb are turned on and at least one ground selection transistor of each of the remaining cell strings CSa, CSc, and CSd is turned off. For example, the first dummy voltage Vd1 may be applied to the 0-th and eighth ground selection lines GSL0 and GSL8. The 0-th dummy voltage Vd0 may be applied to the second, fourth, and sixth ground selection lines GSL2, GSL4, and GSL6. The 0-th voltage V0 may be applied to the first, third, and seventh ground selection lines GSL1, GSL3, and GSL7. The first voltage V1 may be applied to the fifth ground selection line GSL5.

According to the above bias condition, the 7a-th ground selection transistor GST7a may be turned off by the 0-th voltage V0 of the seventh ground selection line GSL7; the 3c-th ground selection transistor GST3c may be turned off by the 0-th voltage V0 of the third ground selection line GSL3; the 1d-th ground selection transistor GST1d may be turned off by the 0-th voltage V0 of the first ground selection line GSL1. All the remaining ground selection transistors may be turned on. Accordingly, the b-th cell string CSb being a selected cell string is electrically connected to the common source line CSL, and the a-th, c-th, and d-th cell strings CSa, CSc, and CSd being an unselected cell string are not electrically connected to the common source line CSL.

Next, in FIG. 10B, it is assumed that the c-th cell string CSc is a selected cell string. In this case, various voltages may be applied to the 0-th to eighth ground selection lines GSL0 to GSL8 such that all the ground selection transistors GST0c to GST8c of the c-th cell string CSc are turned on and at least one ground selection transistor of each of the remaining cell strings CSa, CSb, and CSd is turned off. For example, the first dummy voltage Vd1 may be applied to the 0-th and eighth ground selection lines GSL0 and GSL8. The 0-th dummy voltage Vd0 may be applied to the second, fourth, and sixth ground selection lines GSL2, GSL4, and GSL6. The 0-th voltage V0 may be applied to the first, fifth, and seventh ground selection lines GSL1, GSL5, and GSL7. The first voltage V1 may be applied to the third ground selection line GSL3.

According to the above bias condition, the 7a-th ground selection transistor GST7a may be turned off by the 0-th voltage V0 of the seventh ground selection line GSL7; the 5b-th ground selection transistor GST5b may be turned off by the 0-th voltage V0 of the fifth ground selection line GSL5; the 1d-th ground selection transistor GST1d may be turned off by the 0-th voltage V0 of the first ground selection line GSL1. All the remaining ground selection transistors may be turned on. Accordingly, the c-th cell string CSc being a selected cell string is electrically connected to the common source line CSL, and the a-th, b-th, and d-th cell strings CSa, CSb, and CSd being an unselected cell string are not electrically connected to the common source line CSL.

Next, referring to FIGS. 1, 11A, and 11B, the first memory block BLK1 of the memory device 120 may have the first GSL coding pattern CP1. Because the first GSL coding pattern CP1 of the first memory block BLK1 is described with reference to FIG. 9A, additional description will be omitted to avoid redundancy.

First, in FIG. 11A, it is assumed that the b-th cell string CSb is a selected cell string. In this case, various voltages may be applied to the 0-th to eighth ground selection lines GSL0 to GSL8 such that all the ground selection transistors GST0b to GST8b of the b-th cell string CSb are turned on and at least one ground selection transistor of each of the remaining cell strings CSa, CSc, and CSd is turned off.

For example, the first dummy voltage Vd1 may be applied to the 0-th and eighth ground selection lines GSL0 and GSL8. The 0-th voltage V0 may be applied to the first, second, third, sixth, and seventh ground selection lines GSL1, GSL2, GSL3, GSL6, and GSL7. The first voltage V1 may be applied to the fourth and fifth ground selection lines GSL4 and GSL5. In this case, the 1d-th, 2d-th, 3c-th, 6a-th, and 7a-th ground selection transistors GST1d, GST2d, GST3c, GST6a, and GST7a may be turned off by the 0-th voltages V0 of the first, second, third, sixth, and seventh ground selection lines GSL1, GSL2, GSL3, GSL6, and GSL7 respectively, and the remaining ground selection transistors may be turned on. Accordingly, the b-th cell string CSb being a selected cell string is electrically connected to the common source line CSL, and the a-th, c-th, and d-th cell strings CSa, CSc, and CSd being an unselected cell string are not electrically connected to the common source line CSL.

Next, in FIG. 11B, it is assumed that the c-th cell string CSc is a selected cell string. In this case, various voltages may be applied to the 0-th to eighth ground selection lines GSL0 to GSL8 such that all the ground selection transistors GST0c to GST8c of the c-th cell string CSc are turned on and at least one ground selection transistor of each of the remaining cell strings CSa, CSb, and CSd is turned off.

For example, the first dummy voltage Vd1 may be applied to the 0-th and eighth ground selection lines GSL0 and GSL8. The 0-th voltage V0 may be applied to the first, second, fifth, sixth, and seventh ground selection lines GSL1, GSL2, GSL5, GSL6, and GSL7. The first voltage V1 may be applied to the third and fourth ground selection lines GSL3 and GSL4. In this case, the 1d-th, 2d-th, 5b-th, 6a-th, and 7a-th ground selection transistors GST1d, GST2d, GST5b, GST6a, and GST7a may be turned off by the 0-th voltages V0 of the first, second, fifth, sixth, and seventh ground selection lines GSL1, GSL2, GSL5, GSL6, and GSL7 respectively, and the remaining ground selection transistors may be turned on. Accordingly, the c-th cell string CSc being a selected cell string is electrically connected to the common source line CSL, and the a-th, b-th, and d-th cell strings CSa, CSb, and CSd being an unselected cell string are not electrically connected to the common source line CSL.

As described above, the bias condition of the ground selection lines may vary depending on the GSL coding pattern of the first memory block BLK1. Table 1 below shows the bias conditions of the first memory block BLK1 described with reference to FIGS. 10A to 11B.

TABLE 1

| | 0-th GSL coding pattern CP0 | | | First GSL coding pattern CP1 | | |
|---|---|---|---|---|---|---|
| | | CSb | CSc | | CSb | CSc |
| | GSL Type | Selected | Selected | GSL Type | Selected | Selected |
| GSL8 | dGSL | Vd1 | Vd1 | dGSL | Vd1 | Vd1 |
| GSL7 | CGSL | V0 | V0 | CGSL | V0 | V0 |
| GSL6 | dGSL | Vd0 | Vd0 | CGSL | V0 | V0 |
| GSL5 | CGSL | V1 | V0 | CGSL | V1 | V0 |
| GSL4 | dGSL | Vd0 | Vd0 | CGSL | V1 | V1 |
| GSL3 | CGSL | V0 | V1 | CGSL | V0 | V1 |
| GSL2 | dGSL | Vd0 | Vd0 | CGSL | V0 | V0 |
| GSL1 | CGSL | V0 | V0 | CGSL | V0 | V0 |
| GSL0 | dGSL | Vd1 | Vd1 | dGSL | Vd1 | Vd1 |

Referring to Table 1, the bias condition of the plurality of ground selection lines GSL0 to GSL8 for the 0-th GSL coding pattern CP0 or the first GSL coding pattern CP1 of the first memory block BLK1 is disclosed. The contents of Table 1 are described above, and thus, additional description will be omitted to avoid redundancy. As disclosed in Table 1, even though the same cell string is selected, the bias condition or voltage levels of the plurality of ground selection lines GSL0 to GSL8 may vary depending on the GSL coding pattern (e.g., CP0 or CP1) of the first memory block BLK1. In some implementations, the control logic circuit 126 of the memory device 120 may store or manage information about the GSL coding pattern of the first memory block BLK1. The control logic circuit 126 of the memory device 120 may control ground selection lines of the first memory block BLK1, based on the GSL coding pattern of the first memory block BLK1.

In some implementations, the information about the GSL coding pattern of the first memory block BLK1 may be provided to the memory device 120 by the GSL managing circuit 111 of the controller 110. In some implementations, the controller 110 may provide the information about the GSL coding pattern of the first memory block BLK1 to the memory device 120 by using various commands (e.g., SET FEATURE, GET FEATURE, a reserved command, and a vendor command).

As described above, according to some implementations of the present disclosure, the ground selection lines or ground selection transistors of the first memory block BLK1 of the memory device 120 may have the GSL coding pattern. In this case, when the P/E cycle of the first memory block BLK1 reaches the reference value TH, the controller 110 may perform threshold voltage check operation for the ground selection transistors of the first memory block BLK1; when the check operation is failed, the controller 110 may change or update the GSL coding pattern of the first memory block BLK1. In this case, the reliability of the ground selection transistors of the first memory block BLK1 may be improved. Accordingly, the reliability of both the memory device 120 and the storage device 100 may be improved.

In some implementations, the change or update of the GSL coding pattern for a memory block may be performed by the memory device 120. In this case, the memory device 120 may change or update the GSL coding pattern for the memory block without control of the controller 110. Alternatively, the memory device 120 may change or update the GSL coding pattern for the memory block under control of the controller 110.

In the above implementation, the 0-th GSL coding pattern CP0 and the first GSL coding pattern CP1 of the first memory block BLK1 are partially described as an example, but the present disclosure is not limited thereto. For example, the GSL coding pattern of the first memory block BLK1 may be variously changed.

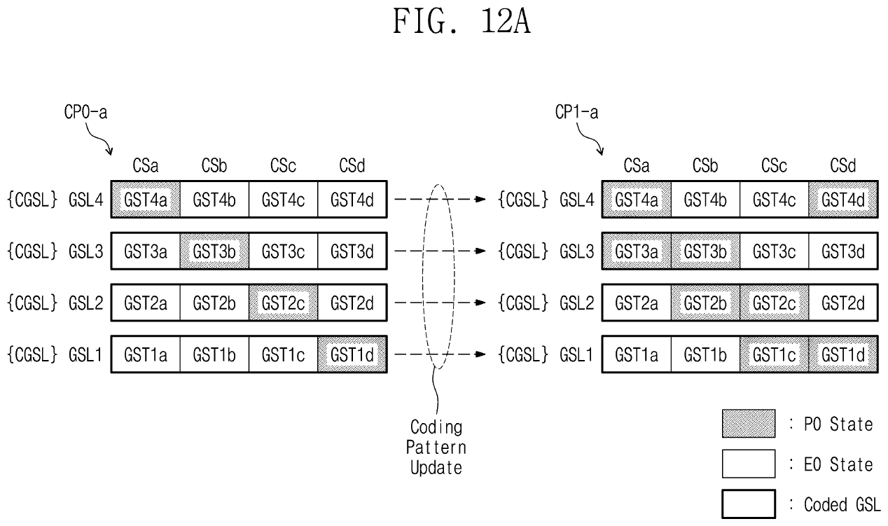

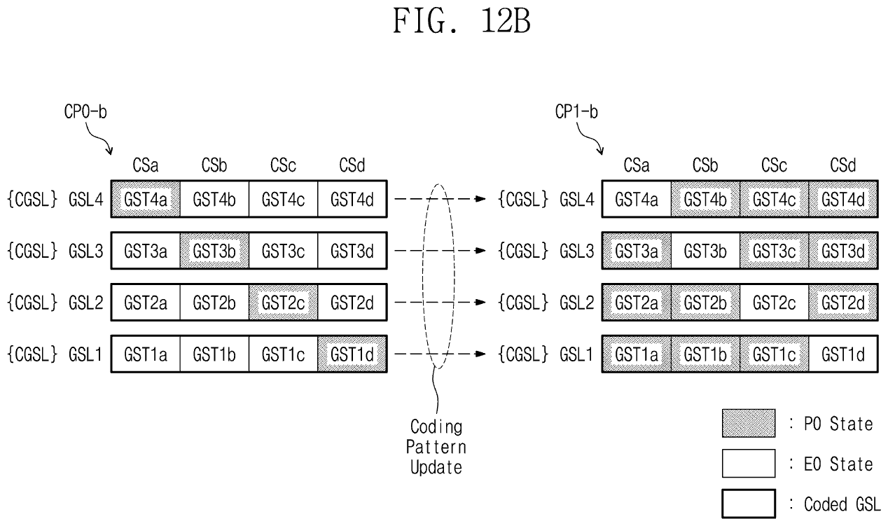

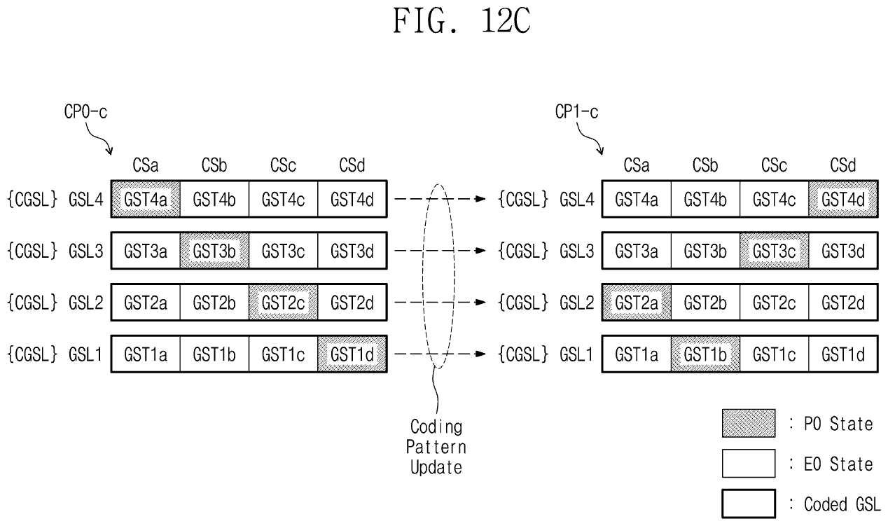

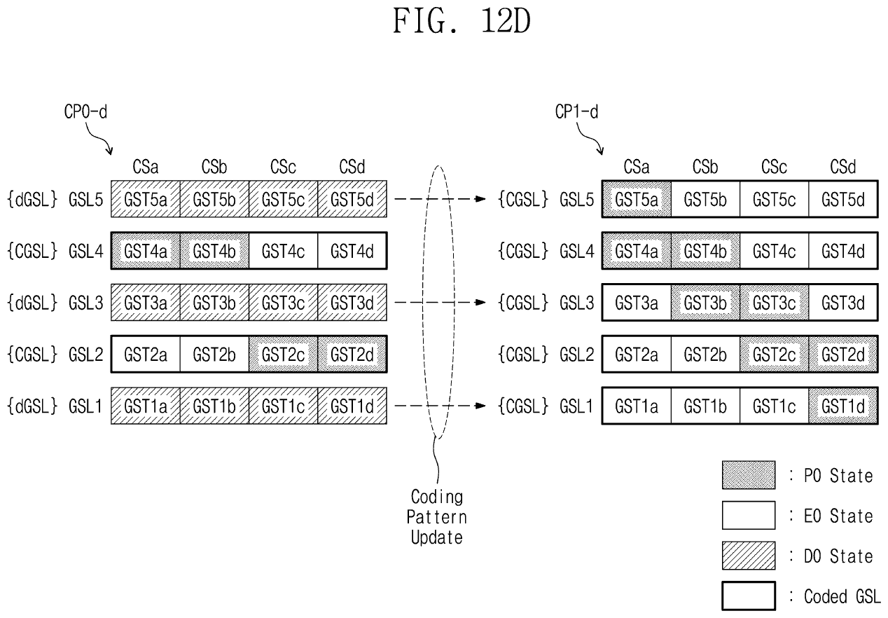

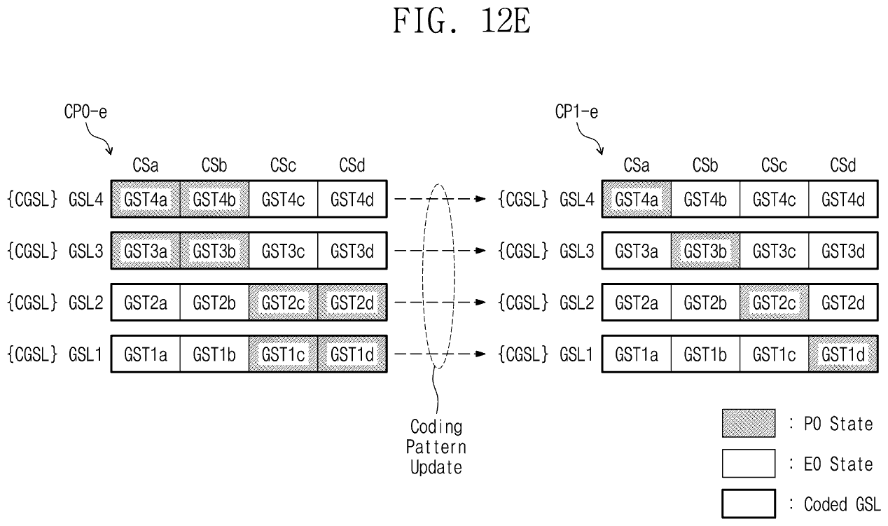

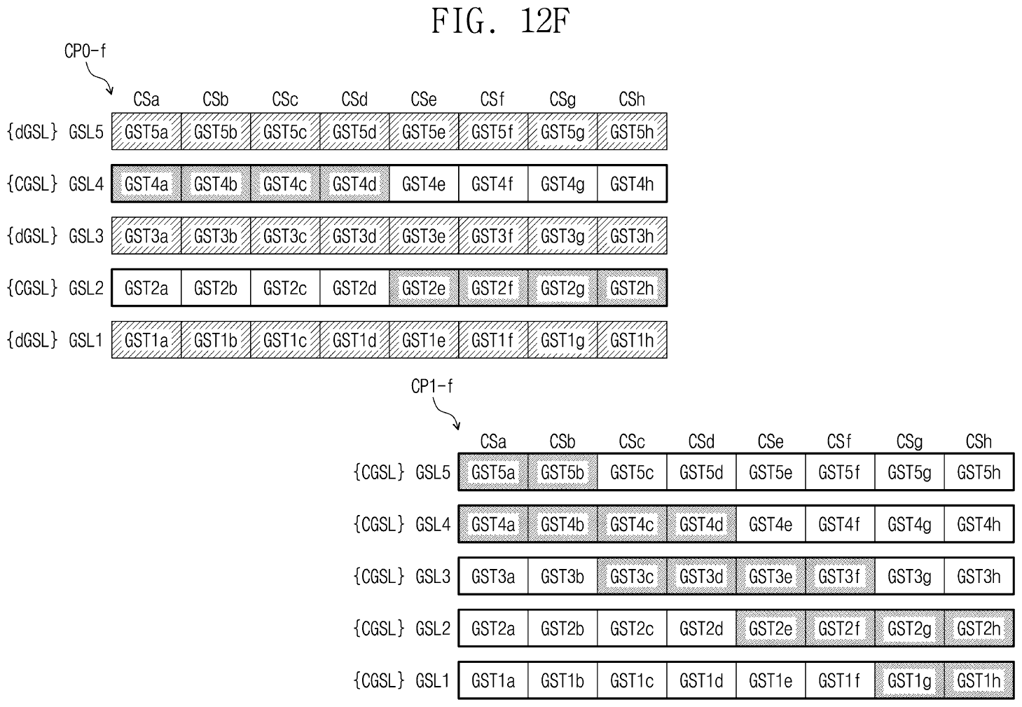

FIGS. 12A, 12B, 12C, 12D, 12E, and 12F are diagrams for describing various example GSL coding patterns of a first memory block. Various GSL coding patterns of the first memory block BLK1 will be described with reference to FIGS. 12A to 12F. However, the present disclosure is not limited thereto. For example, the GSL coding pattern of the first memory block BLK1 may be changed to various forms (or patterns). Also, the bias condition for the ground selection lines of the first memory block BLK1 may vary depending on the GSL coding pattern of the first memory block BLK1. In FIGS. 12A to 12F, for brevity of drawing and for convenience of description, components which are unnecessary to describe the GSL coding pattern of the first memory block BLK1 are omitted.

Referring to FIGS. 1 and 12A to 12F, the first memory block BLK1 may include the first to fourth ground selection lines GSL1 to GSL4. Each of the first to fourth ground selection lines GSL1 to GSL4 may be connected to a plurality of ground selection transistors.

As illustrated in FIG. 12A, the first memory block BLK1 may have a 0-a-th GSL coding pattern CP0-a. In the 0-a-th GSL coding pattern CP0-a, the first to fourth ground selection lines GSL1 to GSL4 may be used as the coding ground selection line CGSL. That is, in the 0-a-th GSL coding pattern CP0-a, the 1d-th, 2c-th, 3b-th, and 4a-th ground selection transistors GST1d, GST2c, GST3b, and GST4a may have the 0-th program state P0, and the remaining ground selection transistors may have the 0-th erase state E0.

The memory device 120 may determine whether the first memory block BLK1 satisfies a specific condition (e.g., the condition that the P/E cycle of the first memory block BLK1 is greater than the reference value TH and a threshold voltage check operation of a ground selection transistor is failed).

When the specific condition is satisfied, the memory device 120 may change or update the GSL coding pattern of the first memory block BLK1 to a 1-a-th GSL coding pattern CP1-a. For example, in the 1-a-th GSL coding pattern CP1-a, the first to fourth ground selection lines GSL1 to GSL4 may be used as the coding ground selection line CGSL. That is, in the 1-a-th GSL coding pattern CP1-a, the 1c-th, 1d-th, 2b-th, 2c-th, 3a-th, 3b-th, 4a-th, and 4d-th ground selection transistors GST1c, GST1d, GST2b, GST2c, GST3a, GST3b, GST4a, and GST4d may have the 0-th program state P0, and the remaining ground selection transistors may have the 0-th erase state E0.

In some implementations, the operation of changing or updating the GSL coding pattern of the first memory block BLK1 from the 0-a-th GSL coding pattern CP0-a to the 1-a-th GSL coding pattern CP1-a may be performed without the erase operation for the first memory block BLK1.

For example, to change or update the 0-a-th GSL coding pattern CP0-a to the 1-a-th GSL coding pattern CP1-a, the memory device 120 may perform the program operation for the first ground selection line GSL1 such that the 1c-th ground selection transistor GST1c is programmed to the 0-th program state P0, may perform the program operation for the second ground selection line GSL2 such that the 2b-th ground selection transistor GST2b is programmed to the 0-th program state P0, may perform the program operation for the third ground selection line GSL3 such that the 3a-th ground selection transistor GST3a is programmed to the 0-th program state P0, and may perform the program operation for the fourth ground selection line GSL4 such that the 4d-th ground selection transistor GST4d is programmed to the 0-th program state P0.

As described above, the memory device 120 may change or update the GSL coding pattern of the first memory block BLK1 by performing the program operation for at least one coding ground selection line without the erase operation for the first memory block BLK1.

Next, as illustrated in FIG. 12B, the first memory block BLK1 may have a 0-b-th GSL coding pattern CP0-b. The 0-b-th GSL coding pattern CP0-b is the same as the 0-a-th GSL coding pattern CP0-a of FIG. 12A, and thus, additional description will be omitted to avoid redundancy.

When the specific condition is satisfied, the memory device 120 may change or update the GSL coding pattern of the first memory block BLK1 to a 1-b-th GSL coding pattern CP1-b. For example, the memory device 120 may perform the erase operation for the first memory block BLK1. Afterwards, the memory device 120 may perform the program operation for the first ground selection line GSL1 such that the 1a-th, 1b-th, and 1c-th ground selection transistors GST1a, GST1b, and GST1c are programmed to the 0-th program state P0, perform the program operation for the second ground selection line GSL2 such that the 2a-th, 2b-th, and 2d-th ground selection transistors GST2a, GST2b, and GST2d are programmed to the 0-th program state P0, perform the program operation for the third ground selection line GSL3 such that the 3a-th, 3c-th, and 3d-th ground selection transistors GST3a, GST3c, and GST3d are programmed to the 0-th program state P0, and perform the program operation for the fourth ground selection line GSL4 such that the 4b-th, 4c-th, and 4d-th ground selection transistors GST4b, GST4c, and GST4d are programmed to the 0-th program state P0.

In some implementations, the 0-b-th GSL coding pattern CP0-b may be a GSL coding pattern based on the 0-th program state P0 (i.e., the P0-based GSL coding pattern), and the 1-b-th GSL coding pattern CP1-b may be a GSL coding pattern based on the 0-th erase state E0 (i.e., the E0-based GSL coding pattern). The P0-based GSL coding pattern may indicate a GSL coding pattern in which one ground selection transistor among ground selection transistors connected to one ground selection line is programmed to the 0-th program state P0 and the remaining ground selection transistors are programmed to the 0-th erase state E0, and the E0-based GSL coding pattern may indicate a GSL coding pattern in which one ground selection transistor among ground selection transistors connected to one ground selection line is programmed to the 0-th erase state E0 and the remaining ground selection transistors are programmed to the 0-th program state P0.

As described above, the memory device 120 may change or update the GSL coding pattern of the first memory block BLK1 from the P0-based GSL coding pattern to the E0-based GSL coding pattern.

Next, as illustrated in FIG. 12C, the first memory block BLK1 may have a 0-c-th GSL coding pattern CP0-c. The 0-c-th GSL coding pattern CP0-c is the same as the 0-a-th GSL coding pattern CP0-a of FIG. 12A, and thus, additional description will be omitted to avoid redundancy.

When the specific condition is satisfied, the memory device 120 may change or update the GSL coding pattern of the first memory block BLK1 to a 1-c-th GSL coding pattern CP1-c. For example, the memory device 120 may perform the erase operation for the first memory block BLK1. Afterwards, the memory device 120 may perform the program operation for the first ground selection line GSL1 such that the 1b-th ground selection transistor GST1b is programmed to the 0-th program state P0, may perform the program operation for the second ground selection line GSL2 such that the 2a-th ground selection transistor GST2a is programmed to the 0-th program state P0, may perform the program operation for the third ground selection line GSL3 such that the 3c-th ground selection transistor GST3c is programmed to the 0-th program state P0, and may perform the program operation for the fourth ground selection line GSL4 such that the 4d-th ground selection transistor GST4d is programmed to the 0-th program state P0.

In some implementations, the 0-c-th GSL coding pattern CP0-c and the 1-c-th GSL coding pattern CP1-c may be the P0-based GSL coding pattern, but the 0-c-th GSL coding pattern CP0-c and the 1-c-th GSL coding pattern CP1-c may have patterns of different forms. That is, the memory device 120 may change or update the first memory block BLK1 to any other GSL coding pattern.

Then, as illustrated in FIG. 12D, the first memory block BLK1 may have a 0-d-th GSL coding pattern CP0-d. In the 0-d-th GSL coding pattern CP0-d, the first, third, and fifth ground selection lines GSL1, GSL3, and GSL5 may be used as the dummy ground selection line dGSL, and the second and fourth ground selection lines GSL2 and GSL4 may be used as the coding ground selection line CGSL.

In the 0-d-th GSL coding pattern CP0-d, the ground selection transistors GST1a to GST1d, GST3a to GST3d, and GST5a to GST5d connected to the first, third, and fifth ground selection lines GSL1, GSL3, and GSL5 may have the 0-th dummy state D0. The 2a-th and 2b-th ground selection transistors GST2a and GST2b connected to the second ground selection line GSL2 may have the 0-th erase state E0, and the 2c-th and 2d-th ground selection transistors GST2c and GST2d may have the 0-th program state P0. The 4a-th and 4b-th ground selection transistors GST4a and GST4b connected to the fourth ground selection line GSL4 may have the 0-th program state P0, and the 4c-th and 4d-th ground selection transistors GST4c and GST4d may have the 0-th erase state E0. In this case, the a-th and b-th cell strings CSa and CSb may be controlled together, and the c-th and d-th cell strings CSc and CSd may be controlled together. That is, the first memory block BLK1 having the 0-d-th GSL coding pattern CP0-d may be controlled based on the 2SSL-1GSL structure. In other words, a plurality of cell strings of the first memory block BLK1 having the 0-d-th GSL coding pattern CP0-d may be controlled in units of two.

When the specific condition is satisfied, the memory device 120 may change or update the 0-d GSL coding pattern CP0-d of the first memory block BLK1 to a 1-d-th GSL coding pattern CP1-d. For example, the memory device 120 may perform the program operation for the first ground selection line GSL1 such that the 1d-th ground selection transistor GST1d is programmed to the 0-th program state P0, may perform the program operation for the third ground selection line GSL3 such that the 3b-th and 3c-th ground selection transistors GST3b and GST3c are programmed to the 0-th program state P0, and may perform the program operation for the fifth ground selection line GSL5 such that the 5a-th ground selection transistor GST5a is programmed to the 0-th program state P0. In this case, the first to fifth ground selection lines GSL1 to GSL5 may be used as the coding ground selection line CGSL.

In some implementations, in the 1-d-th GSL coding pattern CP1-d, the a-th to d-th cell strings CSa to CSd may be controlled individually. For example, when the a-th cell string CSa is selected cell string, the first voltage V1 may be applied to the fourth and fifth ground selection lines GSL4 and GSL5, and the 0-th voltage V0 may be applied to the first to third ground selection lines GSL1 to GSL3. According to the above bias condition, the 1d-th ground selection transistor GST1d may be turned off by the 0-th voltage V0 of the first ground selection line GSL1; the 2c-th the 2d-th ground selection transistors GST2c and GST2d may be turned off by the 0-th voltage V0 of the second ground selection line GSL2; the 3b-th and 3c-th ground selection transistors GST3b and GST3c may be turned off by the 0-th voltage V0 of the third ground selection line GSL3. Accordingly, the b-th, c-th, and d-th cell strings CSb, CSc, and CSd being unselected cell strings are not electrically connected to the common source line CSL. As described above, in the 1-d-th GSL coding pattern CP1-d, cell strings may be controlled individually. In other words, in the 1-d-th GSL coding pattern CP1-d, the first memory block BLK1 may be controlled based on the 1SSL-1GSL structure. In the 1-d-th GSL coding pattern CP1-d, the cell strings of the first memory block BLK1 may be controlled in units of one, that is, individually.

As described above, the memory device 120 may change or update the GSL coding pattern of the first memory block BLK1. In some implementations, the first memory block BLK1 may be controlled based on the 2SSL-1GSL structure or the 1SSL-1GSL structure, depending on the GSL coding pattern of the first memory block BLK1. In this case, the memory device 120 may change the GSL coding pattern of the first memory block BLK1 by performing the program operation for the dummy ground selection lines dGSL without the erase operation for the first memory block BLK1.

Then, as illustrated in FIG. 12E, the first memory block BLK1 may have a 0-e-th GSL coding pattern CP0-e. In the 0-e-th GSL coding pattern CP0-e, the first to fourth ground selection lines GSL1 to GSL4 may be used as the coding ground selection line CGSL. In the 0-e-th GSL coding pattern CP0-e, the 1c-th and 1d-th ground selection transistors GST1c and GST1d connected to the first ground selection line GSL1, the 2c-th and 2d-th ground selection transistors GST2c and GST2d connected to the second ground selection line GSL2, the 3a-th and 3b-th ground selection transistors GST3a and GST3b connected to the third ground selection line GSL3, and the 4a-th and 4b-th ground selection transistors GST4a and GST4b connected to the fourth ground selection line GSL4 may have the 0-th program state P0, and the remaining ground selection transistors may have the 0-th erase state E0. The first memory block BLK1 having the 0-e-th GSL coding pattern CP0-e may be controlled based on the 2SSL-1GSL structure.

When the specific condition is satisfied, the memory device 120 may change or update the GSL coding pattern of the first memory block BLK1 from the 0-e-th GSL coding pattern CP0-e to a 1-e-th GSL coding pattern CP1-e. In some implementations, the 1-e-th GSL coding pattern CP1-e is the same as the 0-a-th GSL coding pattern CP0-a of FIG. 12A, and thus, additional description will be omitted to avoid redundancy. In some implementations, the memory device 120 may perform the erase operation for the first memory block BLK1 and may then perform the program operation for the first to fourth ground selection lines GSL1 to GSL4 such that the 1d-th, 2c-th, 3b-th, and 4a-th ground selection transistors GST1d, GST2c, GST3b, and GST4a have the 0-th program state P0. The first memory block BLK1 having the 1-e-th GSL coding pattern CP1-e may be controlled based on the 1SSL-1GSL structure.

As described above, the memory device 120 may change or update the GSL coding pattern of the first memory block BLK1. In some implementations, the first memory block BLK1 may be controlled based on the 2SSL-1GSL structure or the 1SSL-1GSL structure, depending on the GSL coding pattern of the first memory block BLK1. In some implementations, the memory device 120 may change or update the GSL coding pattern of the first memory block BLK1 by performing the erase operation for the first memory block BLK1 and performing the program operation for the ground selection lines GSL.

For example, as illustrated in FIG. 12F, the first memory block BLK1 may include the a-th to h-th cell strings CSa to CSh. The ground selection transistors GST1a to GST5h of the a-th to h-th cell strings CSa to CSh may be connected to the first to fifth ground selection lines GSL1 to GSL5 respectively.

The first memory block BLK1 may have a 0-f-th GSL coding pattern CP0-f. In the 0-f-th GSL coding pattern CP0-f, the first, third, and fifth ground selection lines GSL1, GSL3, and GSL5 may be used as the dummy ground selection line dGSL, and the second and fourth ground selection lines GSL2 and GSL4 may be used as the coding ground selection line CGSL. In the 0-f-th GSL coding pattern CP0-f, the ground selection transistors GST1a to GST1h, GST3a to GST3h, and GST5a to GST5h connected to the first, third, and fifth ground selection lines GSL1, GSL3, and GSL5 may have the 0-th dummy state D0. The 2a-th to 2d-th ground selection transistors GST2a to GST2d connected to the second ground selection line GSL2 may have the 0-th erase state E0, and the 2e-th to 2h-th ground selection transistors GST2e to GST2h may have the 0-th program state P0. The 4a-th to 4d-th ground selection transistors GST4a to GST4d connected to the fourth ground selection line GSL4 may have the 0-th program state P0, and the 4e-th to 4h-th ground selection transistors GST4e to GST4h may have the 0-th erase state E0. In this case, the a-th to d-th cell strings CSa to CSd may be controlled together, and the e-th to h-th cell strings CSe to CSh may be controlled together. That is, the first memory block BLK1 having the 0-f-th GSL coding pattern CP0-f may be controlled based on the 4SSL-1GSL structure. In other words, cell strings of the first memory block BLK1 having the 0-f-th GSL coding pattern CP0-f may be controlled in units of four.

When the specific condition is satisfied, the memory device 120 may change or update the 0-f-th GSL coding pattern CP0-f of the first memory block BLK1 to a 1-f-th GSL coding pattern CP1-f. For example, the memory device 120 may perform the program operation for the first ground selection line GSL1 such that the 1g-th and 1h-th ground selection transistors GST1g and GST1h are programmed to the 0-th program state P0, may perform the program operation for the third ground selection line GSL3 such that the 3c-th to 3f-th ground selection transistors GST3c to GST3f are programmed to the 0-th program state P0, and may perform the program operation for the fifth ground selection line GSL5 such that the 5a-th and 5b-th ground selection transistors GST5a and GST5b are programmed to the 0-th program state P0. In this case, the first to fifth ground selection lines GSL1 to GSL5 may be used as the coding ground selection line CGSL.

In the 1-f-th GSL coding pattern CP1-f, the a-th and b-th cell strings CSa and CSb may be controlled together, the c-th and d-th cell strings CSc and CSd may be controlled together, the e-th and f-th cell strings CSe and CSf may be controlled together, and the g-th and h-th cell strings CSg and CSh may be controlled together. That is, in the 1-f-th GSL coding pattern CP1-f, the first memory block BLK1 may be controlled based on the 2SSL-1GSL structure. In other words, in the 1-f-th GSL coding pattern CP1-f, cell strings of the first memory block BLK1 may be controlled in units of two.

As described above, the memory device 120 may change or update the GSL coding pattern of the first memory block BLK1. In some implementations, the first memory block BLK1 may be controlled based on the 4SSL-1GSL structure or the 2SSL-1GSL structure, depending on the GSL coding pattern of the first memory block BLK1.

The implementation in which the first memory block BLK1 is changed from the GSL coding pattern of the 2SSL-1GSL structure to the GSL coding pattern of the 1SSL-1GSL structure and the implementation in which the first memory block BLK1 is changed from the GSL coding pattern of the 4SSL-1GSL structure to the GSL coding pattern of the 2SSL-1GSL structure are described above, but the present disclosure is not limited thereto. For example, the GSL coding pattern of the first memory block BLK1 may be changed from the GSL coding pattern of the nSSL-1GSL structure to the GSL coding pattern of the mSSL-1GSL structure (n and m being different or the same positive integers). Accordingly, a plurality of cell strings of the first memory block BLK1 may be controlled in units of “n” before the GSL coding pattern is changed and may be controlled in units of “m” after the GSL coding pattern is changed.

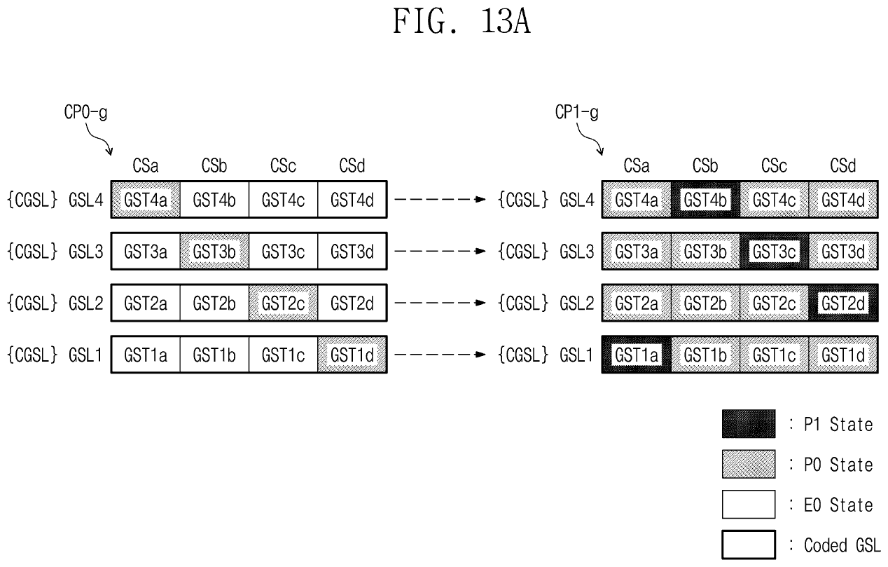

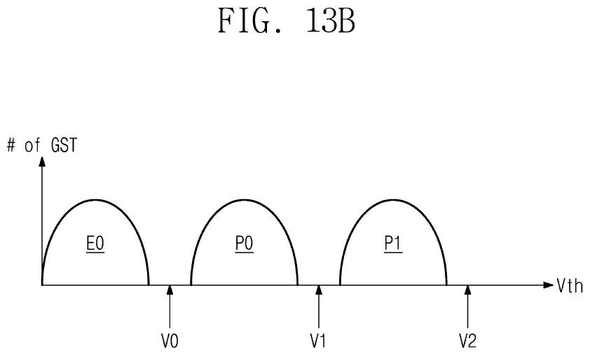

FIGS. 13A and 13B are diagrams for describing an example of a GSL coding pattern of a first memory block. For convenience of description, components which are unnecessary to describe the GSL coding pattern of the first memory block BLK1 are omitted.

Referring to FIGS. 1, 4, 13A, and 13B, the ground selection transistors GST of the first memory block BLK1 may have the 0-th erase state E0, the 0-th program state P0, or a first program state P1 depending on the GSL coding pattern. For example, as illustrated in FIG. 13A, the first memory block BLK1 may have the 0-g-th GSL coding pattern CP0-g. The 0-g-th GSL coding pattern CP0-g is the same as the 0-a-th GSL coding pattern CP0-a of FIG. 12A, and thus, additional description will be omitted to avoid redundancy.

When the specific condition is satisfied, the memory device 120 may change or update the 0-g-th GSL coding pattern CP0-g of the first memory block BLK1 to a 1-g-th GSL coding pattern CP1-g. For example, the memory device 120 may perform the program operation for the first ground selection line GSL1 such that the 1a-th ground selection transistor GST1a is programmed to the first program state P1 and the 1b-th, 1c-th, and 1d-th ground selection transistors GST1b, GST1c, and GST1d are programmed to the 0-th program state P0. The memory device 120 may perform the program operation for the second ground selection line GSL2 such that the 2d-th ground selection transistor GST2d is programmed to the first program state P1 and the 2a-th, 2b-th, and 2c-th ground selection transistors GST2a, GST2b, and GST2c are programmed to the 0-th program state P0. The memory device 120 may perform the program operation for the third ground selection line GSL3 such that the 3c-th ground selection transistor GST3c is programmed to the first program state P1 and the 3a-th, 3b-th, and 3d-th ground selection transistors GST3a, GST3b, and GST3d are programmed to the 0-th program state P0. The memory device 120 may perform the program operation for the fourth ground selection line GSL4 such that the 4b-th ground selection transistor GST4b is programmed to the first program state P1 and the 4a-th, 4c-th, and 4d-th ground selection transistors GST4a, GST4c, and GST4d are programmed to the 0-th program state P0.

In some implementations, compared to the 0-g-th GSL coding pattern CP0-g, the ground selection transistors of the 1-g-th GSL coding pattern CP1-g may have a relatively high threshold voltage state. For example, in the 0-g-th GSL coding pattern CP0-g, the ground selection transistors have the 0-th erase state E0 or the 0-th program state P0. In contrast, in the 1-g-th GSL coding pattern CP1-g, the ground selection transistors have the 0-th program state P0 or the first program state P1. In this case, as illustrated in FIG. 13B, the first program state P1 may be a threshold voltage state higher than the 0-th program state P0, and the 0-th program state P0 may be a threshold voltage state higher than the 0-th erase state E0.

In some implementations, the ground selection transistors of the 0-th erase state E0 may be turned on by the 0-th voltage V0, the first voltage V1, and a second voltage V2. Ground selection transistors of the 0-th program state P0 may be turned off by the 0-th voltage V0 and may be turned on by the first voltage V1 and the second voltage V2. Ground selection transistor of the first program state P1 may be turned off by the 0-th voltage V0 and the first voltage V1 and may be turned on by the second voltage V2.

When the above specific condition is satisfied, the memory device 120 may change or update the GSL coding pattern by reprogramming a threshold voltage state of ground selection transistors to a higher threshold voltage state.

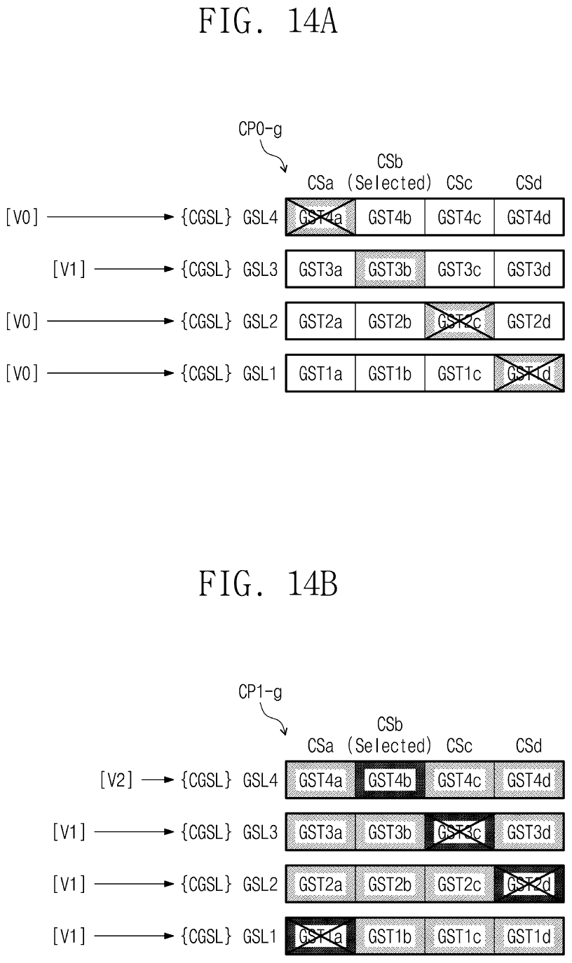

FIGS. 14A and 14B are diagrams for describing an example of a bias condition according to a GSL coding pattern of a first memory block of FIG. 13A. Referring to FIGS. 1, 4, 13A, and 14A, the first memory block BLK1 may have the 0-g-th GSL coding pattern CP0-g. The 0-g-th GSL coding pattern CP0-g is described above, and thus, additional description will be omitted to avoid redundancy.

As illustrated in FIG. 14A, it is assumed that the b-th cell string CSb is a selected cell string. In this case, the 0-th voltage V0 may be applied to the first, second, and fourth ground selection lines GSL1, GSL2, and GSL4, and the first voltage V1 may be applied to the third ground selection line GSL3. According to the above bias condition, the 1d-th ground selection transistor GST1d may be turned off by the 0-th voltage V0 of the first ground selection line GSL1; the 2c-th ground selection transistor GST2c may be turned off by the 0-th voltage V0 of the second ground selection line GSL2; the 4a-th ground selection transistor GST4a may be turned off by the 0-th voltage V0 of the fourth ground selection line GSL4. Accordingly, the a-th, c-th, and d-th cell strings CSa, CSc, and CSd being unselected cell strings are not electrically connected to the common source line CSL.

Next, referring to FIGS. 1, 4, 13A, and 14B, the first memory block BLK1 may have the 1-g-th GSL coding pattern CP1-g. The 1-g-th GSL coding pattern CP1-g is described above, and thus, additional description will be omitted to avoid redundancy.

As illustrated in FIG. 14B, it is assumed that the b-th cell string CSb is a selected cell string. In this case, the first voltage V1 may be applied to the first, second, and third ground selection lines GSL1, GSL2, and GSL3, and the second voltage V2 may be applied to the fourth ground selection line GSL4. According to the above bias condition, the 1a-th ground selection transistor GST1a may be turned off by the first voltage V1 of the first ground selection line GSL1; the 2d-th ground selection transistor GST2d may be turned off by the first voltage V1 of the second ground selection line GSL2; the 3c-th ground selection transistor GST3c may be turned off by the first voltage V1 of the third ground selection line GSL3. Accordingly, the a-th, c-th, and d-th cell strings CSa, CSc, and CSd being unselected cell strings are not electrically connected to the common source line CSL.

As described above, when the first memory block BLK1 has the 0-g-th GSL coding pattern CP0-g, the memory device 120 may control ground selection lines by using the 0-th voltage V0 and the first voltage V1. In contrast, when the first memory block BLK1 has the 1-g-th GSL coding pattern CP1-g, the memory device 120 may control ground selection lines by using the first voltage V1 and the second voltage V2. That is, when the first memory block BLK1 has the 1-g-th GSL coding pattern CP1-g, the memory device 120 may control ground selection lines by using relatively high voltages.

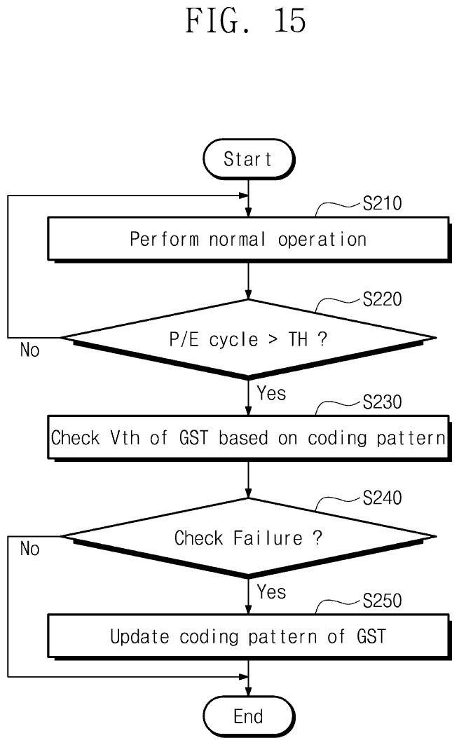

FIG. 15 is a flowchart illustrating an example of an operation of a memory device of FIG. 1. Referring to FIGS. 1 and 15, the memory device 120 may perform operation S210 and operation S220. Operation S210 and operation S220 are similar to operation S110 and operation S120 of FIG. 7, and thus, additional description will be omitted to avoid redundancy.

In operation S230, the memory device 120 may check threshold voltages of ground selection transistors of the first memory block BLK1 based on a GSL coding pattern. As described above, the first memory block BLK1 may have one of various GSL coding patterns. In some implementations, the controller 110 may check the threshold voltages of the ground selection transistors of the first memory block BLK1, based on the GSL coding pattern of the first memory block BLK1.

For example, the first memory block BLK1 may have the 0-th GSL coding pattern CP0 of FIG. 9A. In this case, the controller 110 may perform the check operation for the lower limit level Vb of the 0-th program state P0 of the ground selection transistors of the first memory block BLK1. As an example, as described with reference to FIGS. 9A to 9D, the 0-th GSL coding pattern CP0 may be a pattern relatively robust for the hot electron injection (HCI). That is, when the first memory block BLK1 has the 0-th GSL coding pattern CP0, the hot electron injection phenomenon for the ground selection transistors of the first memory block BLK1 may decrease. This means that there is prevented or decreased the phenomenon that the threshold voltages of the ground selection transistors of the first memory block BLK1 increase. That is, when the first memory block BLK1 has the 0-th GSL coding pattern CP0, the probability that the threshold voltages of the ground selection transistors of the first memory block BLK1 decrease due to the retention characteristic may be high. Accordingly, when the first memory block BLK1 has the 0-th GSL coding pattern CP0, the controller 110 may perform the check operation for the lower limit level Vb of the 0-th program state P0 of the ground selection transistors of the first memory block BLK1 and may detect a threshold voltage decrease phenomenon of the ground selection transistors.

Alternatively, the first memory block BLK1 may have the first GSL coding pattern CP1 of FIG. 9A. In this case, the controller 110 may perform the check operation for the upper limit level Va of the 0-th erase state E0 of the ground selection transistors of the first memory block BLK1. As an example, as described with reference to FIGS. 9A to 9E, the first GSL coding pattern CP1 may be a pattern relatively robust for the retention characteristic. That is, when the first memory block BLK1 has the first GSL coding pattern CP1, the retention phenomenon for the ground selection transistors of the first memory block BLK1 may decrease. This means that there is prevented or decreased the phenomenon that the threshold voltages of the ground selection transistors of the first memory block BLK1 decrease. That is, when the first memory block BLK1 has the first GSL coding pattern CP1, the probability that the threshold voltages of the ground selection transistors of the first memory block BLK1 decrease due to the hot electron injection may be high. Accordingly, when the first memory block BLK1 has the first GSL coding pattern CP1, the controller 110 may perform the check operation for the upper limit level Va of the 0-th erase state E0 of the ground selection transistors of the first memory block BLK1 and may detect a threshold voltage increase phenomenon of the ground selection transistors.

In operation S240, the memory device 120 may determine whether the threshold voltage check operation is failed. When the threshold voltage check operation is failed, in operation S250, the memory device 120 may change or update the GSL coding pattern of the ground selection transistors of the first memory block BLK1. In some implementations, the memory device 120 may change or update the GSL coding pattern of the first memory block BLK1 based on one of the various GSL coding patterns described above.

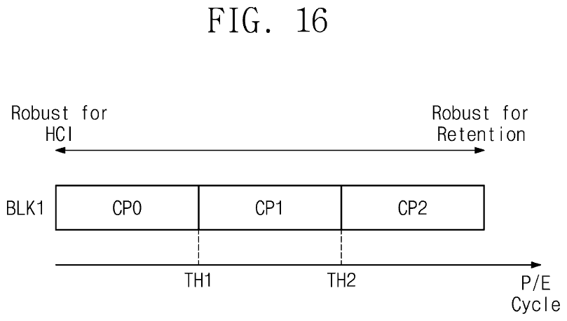

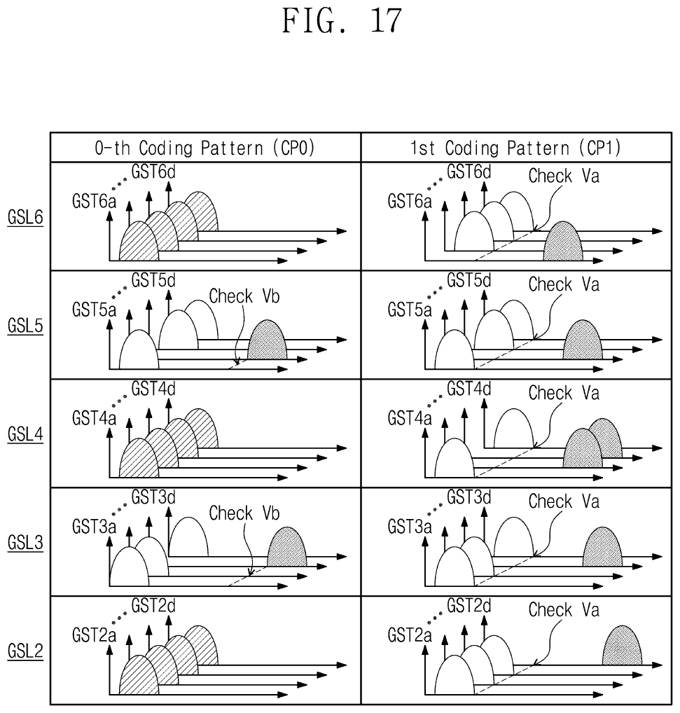

FIGS. 16 and 17 are diagram for describing the update of an example of a GSL coding pattern according to the flowchart of FIG. 15. Referring to FIGS. 1, 15, 16, and 17, in the early part of the P/E cycle, the first memory block BLK1 may have the 0-th GSL coding pattern CP0. When the P/E cycle of the first memory block BLK1 reaches a first reference value TH1, the memory device 120 may perform a first threshold voltage check operation for the ground selection transistors of the first memory block BLK1. When the first threshold voltage check operation is failed, the GSL coding pattern of the first memory block BLK1 may be changed to the first GSL coding pattern CP1.

Afterwards, when the P/E cycle of the first memory block BLK1 reaches a second reference value TH2, the memory device 120 may perform a second threshold voltage check operation for the ground selection transistors of the first memory block BLK1. When the second threshold voltage check operation is failed, the GSL coding pattern of the first memory block BLK1 may be changed to a second GSL coding pattern CP2.

As described above, the GSL coding pattern for the first memory block BLK1 may be repeatedly changed or updated depending on the P/E cycle of the first memory block BLK1.

In some implementations, the 0-th GSL coding pattern CP0 in the early part of the P/E cycle of the first memory block BLK1 may be a pattern relatively robust for the hot electron injection, and the first GSL coding pattern CP1 or the second GSL coding pattern CP2 in the latter part of the P/E cycle of the first memory block BLK1 may be a pattern relatively robust for the retention characteristic. Accordingly, the first threshold voltage check operation may include an operation of detecting the decrease in the threshold voltages of the ground selection transistors, and the second threshold voltage check operation may include an operation of detecting the increase in the threshold voltages of the ground selection transistors.

For example, as illustrated in FIG. 17, when the first memory block BLK1 has the 0-th GSL coding pattern CP0, the first threshold voltage check operation may include an operation of detecting the lower limit level Vb of ground selection transistors (e.g., GST5b and GST3c) of the 0-th program state P0. The reason is that because the 0-th GSL coding pattern CP0 is relatively robust for the hot electron injection, the probability that the threshold voltages of the ground selection transistors decrease is high.

When the first memory block BLK1 has the first GSL coding pattern CP1, the second threshold voltage check operation may include an operation of detecting the upper limit level Va of ground selection transistors (e.g., GST2a, GST2b, GST2c, GST3a, GST3b, GST3b, GST4a, GST4d, GST5a, GST5c, GST5d, GST6b, GST6c, and GST6d) of the 0-th erase state E0. The reason is that because the first GSL coding pattern CP1 is relatively robust for the retention characteristic, the probability that the threshold voltages of the ground selection transistors increase is high.

As described above, the GSL coding pattern of the first memory block BLK1 may be variously changed or updated, and the threshold voltage check operation may be variously modified based on the GSL coding pattern of the first memory block BLK1.

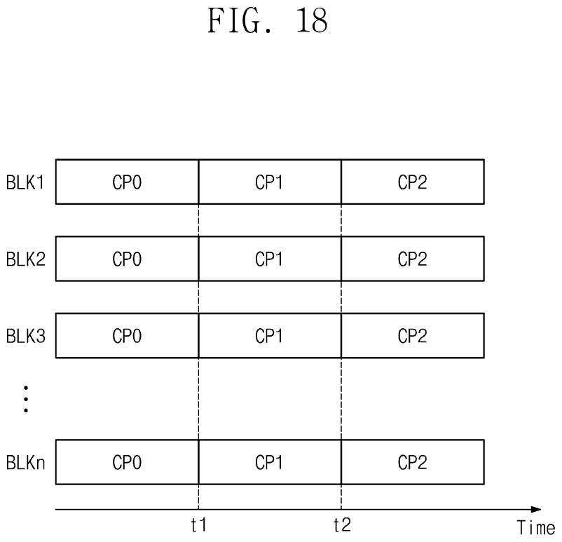

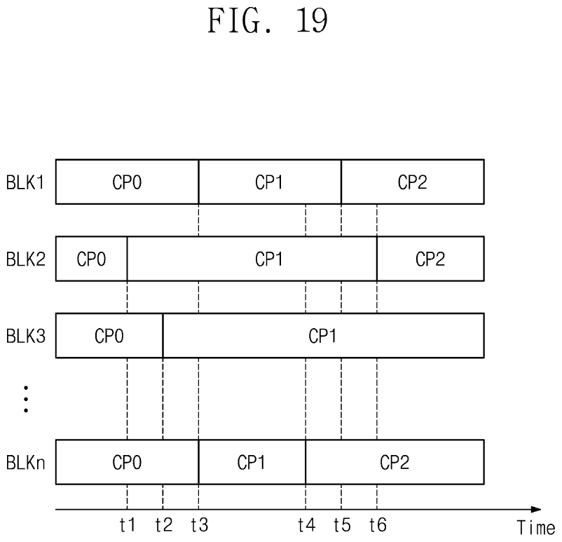

FIGS. 18 and 19 are diagrams for describing an example of an operation of a memory device of FIG. 1. Referring to FIGS. 1, 3, 4, 18, and 19, the memory device 120 may include a plurality of memory blocks BLK1 to BLKn. Each of the plurality of memory blocks BLK1 to BLKn may be identical or similar in structure to the first memory block BLK1 of FIG. 4.

The controller 110 configured to control the memory device 120 may manage or update the GSL coding patterns of the plurality of memory blocks BLK1 to BLKn. For example, each of the plurality of memory blocks BLK1 to BLKn may include a plurality of ground selection transistors GST, and the plurality of ground selection transistors GST may have different threshold voltage states depending on the GSL coding patterns. Accordingly, a bias condition for controlling the plurality of memory blocks BLK1 to BLKn may vary depending on the GSL coding patterns. Accordingly, the controller 110 or the memory device 120 may manage or store information about the GSL coding pattern of each of the plurality of memory blocks BLK1 to BLKn and may determine the bias condition for controlling ground selection lines of the plurality of memory blocks BLK1 to BLKn based on the information about the GSL coding pattern.

In some implementations, the GSL coding patterns of the plurality of memory blocks BLK1 to BLKn may be simultaneously changed or updated. For example, as illustrated in FIG. 18, the plurality of memory blocks BLK1 to BLKn may have the 0-th GSL coding pattern CP0. In this case, each of the plurality of memory blocks BLK1 to BLKn may be controlled based on the bias condition corresponding to the 0-th GSL coding pattern CP0.

At a first time point t1, the specific condition may be satisfied. For example, at the first time point t1, the threshold voltage check operation for at least one memory block among the plurality of memory blocks BLK1 to BLKn may be failed. In this case, all the GSL coding patterns of the plurality of memory blocks BLK1 to BLKn may be changed to the first GSL coding pattern CP1. After the first time point t1, each of the plurality of memory blocks BLK1 to BLKn may be controlled based on the bias condition corresponding to the first GSL coding pattern CP1.

At a second time point t2, the specific condition may be satisfied. For example, at the second time point t2, the threshold voltage check operation for at least one memory block among the plurality of memory blocks BLK1 to BLKn may be failed. In this case, all the GSL coding patterns of the plurality of memory blocks BLK1 to BLKn may be changed to the second GSL coding pattern CP2. That is, after the second time point t2, each of the plurality of memory blocks BLK1 to BLKn may be controlled based on the bias condition corresponding to the second GSL coding pattern CP2.

As described above, when the specific condition is satisfied, the memory device 120 may change or update all the GSL coding patterns of the plurality of memory blocks BLK1 to BLKn to the same GSL coding pattern. In this case, the controller 110 or the memory device 120 may manage information about the changed GSL coding pattern and may control the plurality of memory blocks BLK1 to BLKn based on the information about the changed GSL coding pattern.

In some implementations, the GSL coding patterns of the plurality of memory blocks BLK1 to BLKn may be individually or independently changed or updated. For example, as illustrated in FIG. 19, the plurality of memory blocks BLK1 to BLKn may have the 0-th GSL coding pattern CP0. In this case, each of the plurality of memory blocks BLK1 to BLKn may be controlled based on the bias condition corresponding to the 0-th GSL coding pattern CP0.

At a first time point t1, the specific condition of the second memory block BLK2 may be satisfied. For example, at the first time point t1, the threshold voltage check operation for the second memory block BLK2 may be failed. In this case, the GSL coding patterns of the second memory block BLK2 may be changed to the first GSL coding pattern CP1. At a second time point t2, the specific condition of the third memory block BLK3 may be satisfied. In this case, the GSL coding patterns of the third memory block BLK3 may be changed to the first GSL coding pattern CP1. At a third time point t3, the specific condition of the first and n-th memory blocks BLK1 and BLKn may be satisfied. In this case, the GSL coding patterns of the first and n-th memory blocks BLK1 and BLKn may be changed to the first GSL coding pattern CP1. At a fourth time point t4, the specific condition of the n-th memory block BLKn may be satisfied. In this case, the GSL coding patterns of the n-th memory block BLKn may be changed to the second GSL coding pattern CP2. At a fifth time point t5, the specific condition of the first memory block BLK1 may be satisfied. In this case, the GSL coding pattern of the first memory block BLK1 may be changed to the second GSL coding pattern CP2. At a sixth time point t6, the specific condition of the second memory block BLK2 may be satisfied. In this case, the GSL coding pattern of the second memory block BLK2 may be changed to the second GSL coding pattern CP2.

The bias condition of each of the plurality of memory blocks BLK1 to BLKn may be individually controlled. For example, in the time period from t2 to t3, the first memory block BLK1 may have the 0-th GSL coding pattern CP0, the second memory block BLK2 may have the first GSL coding pattern CP1, the third memory block BLK3 may have the first GSL coding pattern CP1, and the n-th memory block BLKn may have the 0-th GSL coding pattern CP0. That is, in the time period from t2 to t3, the first memory block BLK1 may be controlled based on a 0-th bias condition corresponding to the 0-th GSL coding pattern CP0, the second memory block BLK2 may be controlled based on a first bias condition corresponding to the first GSL coding pattern CP1, the third memory block BLK3 may be controlled based on the first bias condition corresponding to the first GSL coding pattern CP1, and the n-th memory block BLKn may be controlled based on the 0-th bias condition corresponding to the 0-th GSL coding pattern CP0.

That is, the GSL coding patterns of the plurality of memory blocks BLK1 to BLKn may be individually controlled; in this case, at the same time point, the plurality of memory blocks BLK1 to BLKn may have different GSL coding patterns. Accordingly, the controller 110 or the memory device 120 may individually manage or store information about the GSL coding pattern of each of the plurality of memory blocks BLK1 to BLKn and may control each of the plurality of memory blocks BLK1 to BLKn based on the information about the GSL coding pattern.

In the above implementations, a configuration of changing or updating the GSL coding patterns of the plurality of memory blocks BLK1 to BLKn simultaneously (or together) or individually is described, but the present disclosure is not limited thereto. For example, the plurality of memory blocks BLK1 to BLKn may be classified into memory block groups, and the GSL coding pattern may be changed or updated in units of memory block group. Alternatively, the plurality of memory blocks BLK1 to BLKn may be classified in units of super block, and the GSL coding pattern may be changed or updated in units of super block.

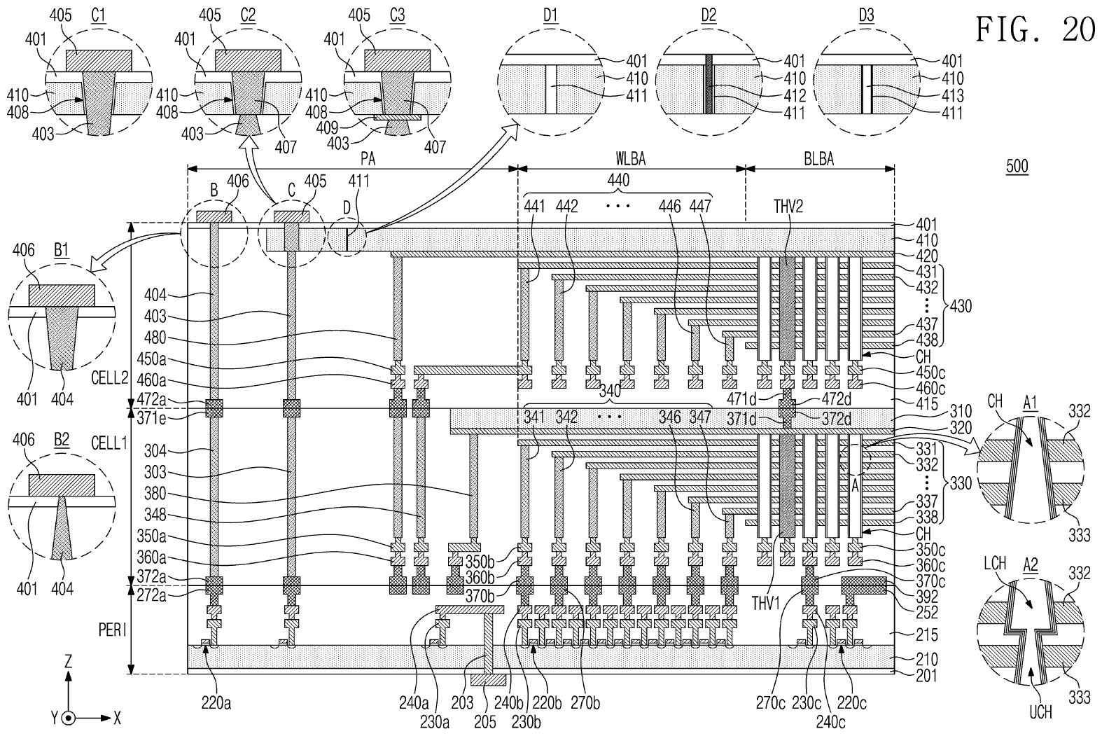

FIG. 20 is a view for describing an example of a memory device 500.

Referring to FIG. 20, the memory device 500 may have a chip-to-chip (C2C) structure. Herein, in the C2C structure, after fabricating at least one upper chip including a cell region CELL and at least one lower chip including a peripheral circuit region PERI, respectively, the upper chip and the lower chip may be bonded to each other by a bonding method. As an example, the bonding method may mean a method of electrically or physically connecting a bonding metal pattern formed in the uppermost metal layer of the upper chip and a bonding metal pattern formed in the uppermost metal layer of the lower chip. For example, when the bonding metal patterns are formed of copper (Cu), the bonding method may be referred to as a “Cu—Cu bonding method”. As another example, the bonding metal patterns may also be formed of aluminum (Al) or tungsten (W).

The memory device 500 may include at least one upper chip including a cell region. For example, as illustrated in FIG. 20, the memory device 500 may be implemented to include two upper chips. However, this is illustrative, and the number of upper chips is not limited thereto. In the case in which the memory device 500 is implemented to include two upper chips, the memory device 500 may be manufactured by separately manufacturing a first upper chip including a first cell region CELL1, a second upper chip including a second cell region CELL2, and a lower chip including a peripheral circuit region PERI and thereafter connecting the first upper chip, the second upper chip, and the lower chip by a bonding method. The first upper chip may be turned over and connected to the lower chip by the bonding method, and the second upper chip may also be turned over and connected to the first upper chip by the bonding method. In the following description, upper portions and lower portions of the first and second upper chips are defined based on before the first upper chip and the second upper chip are turned over. That is, in FIG. 20, an upper portion of the lower chip refers to an upper portion defined based on a +Z-axis direction, and the upper portions of the first and second upper chips refer to upper portions defined based on a-Z-axis direction. However, this is illustrative, and only one of the first upper chip and the second upper chip may be turned over and connected by the bonding method.

Each of the peripheral circuit region PERI and the first and second cell regions CELL1 and CELL2 of the memory device 500 may include an external pad bonding region PA, a word line bonding region WLBA, and a bit line bonding region BLBA.

The peripheral circuit region PERI may include a first substrate 210 and a plurality of circuit elements 220a, 220b, and 220c formed on the first substrate 210. An interlayer insulating layer 215 including one or more insulating layers may be provided on the plurality of circuit elements 220a, 220b, and 220c, and a plurality of metal lines connecting the plurality of circuit elements 220a, 220b, and 220c may be provided in the interlayer insulating layer 215. For example, the plurality of metal lines may include first metal lines 230a, 230b, and 230c connected with the plurality of circuit elements 220a, 220b, and 220c, respectively, and second metal lines 240a, 240b, and 240c formed on the first metal lines 230a, 230b, and 230c. The plurality of metal lines may be formed of at least one of various conductive materials. For example, the first metal lines 230a, 230b, and 230c may be formed of tungsten having a relatively high electrical resistivity, and the second metal lines 240a, 240b, and 240c may be formed of copper having a relatively low electrical resistivity.

In this specification, only the first metal lines 230a, 230b, and 230c and the second metal lines 240a, 240b, and 240c are illustrated and described. However, without being limited thereto, one or more additional metal lines may be further formed on the second metal lines 240a, 240b, and 240c. In this case, the second metal lines 240a, 240b, and 240c may be formed of aluminum At least a portion of the additional metal lines formed on the second metal lines 240a, 240b, and 240c may be formed of copper having a lower electrical resistivity than the aluminum of the second metal lines 240a, 240b, and 240c.

The interlayer insulating layer 115 may be disposed on the first substrate 210 and may include an insulating material, such as silicon oxide or silicon nitride.

Each of the first and second cell regions CELL1 and CELL2 may include at least one memory block. The first cell region CELL1 may include a second substrate 310 and a common source line 320. A plurality of word lines 331 to 338 (hereinafter collectively referred to as “330”) may be stacked on the second substrate 310 in a direction (the Z-axis direction) perpendicular to an upper surface of the second substrate 310. String selection lines and a ground selection line may be disposed on and under the word lines 330, and the plurality of word lines 330 may be disposed between the string selection lines and the ground selection line. Likewise, the second cell region CELL2 may include a third substrate 410 and a common source line 420, and a plurality of word lines 431 to 438 (hereinafter collectively referred to as “430”) may be stacked in a direction (the Z-axis direction) perpendicular to an upper surface of the third substrate 410. The second substrate 310 and the third substrate 410 may be formed of various materials and may be, for example, silicon substrates, silicon-germanium substrates, germanium substrates, or substrates having mono-crystalline epitaxial layers grown on mono-crystalline silicon substrates. A plurality of channel structures CH may be formed in the first and second cell regions CELL1 and CELL2.

In some implementations, as illustrated in A1 (as an alternative example of region A), the channel structure CH may be provided in the bit line bonding region BLBA and may extend in the direction perpendicular to the upper surface of the second substrate 310 to penetrate the word lines 330, the string selection lines, and the ground selection line. The channel structure CH may include a data storage layer, a channel layer, and a buried insulating layer. The channel layer may be electrically connected with a first metal line 350c and a second metal line 360c in the bit line bonding region BLBA. For example, the second metal line 360c may be a bit line and may be connected to the channel structure CH through the first metal line 350c. The bit line 360c may extend in a first direction (a Y-axis direction) parallel to the upper surface of the second substrate 310.

In some implementations, as illustrated in A2 (as an alternative example of region A), the channel structure CH may include a lower channel LCH and an upper channel UCH connected to each other. For example, the channel structure CH may be formed through a process for the lower channel LCH and a process for the upper channel UCH. The lower channel LCH may extend in the direction perpendicular to the upper surface of the second substrate 310 and may penetrate the common source line 320 and the lower word lines 331 and 332. The lower channel LCH may include a data storage layer, a channel layer, and a buried insulating layer and may be connected with the upper channel UCH. The upper channel UCH may penetrate the upper word lines 333 to 338. The upper channel UCH may include a data storage layer, a channel layer, and a buried insulating layer, and the channel layer of the upper channel UCH may be electrically connected with the first metal line 350c and the second metal line 360c. As the length of a channel is increased, it may be difficult to form a channel having a constant width due to process reasons. The memory device 500 according to some implementations of the present disclosure may include a channel having improved width uniformity through the lower channel LCH and the upper channel UCH formed by sequential processes.

In the case in which the channel structure CH includes the lower channel LCH and the upper channel UCH as illustrated in A2, a word line located near the boundary between the lower channel LCH and the upper channel UCH may be a dummy word line. For example, the word line 332 and the word line 333 that form the boundary between the lower channel LCH and the upper channel UCH may be dummy word lines. In this case, data may not be stored in memory cells connected to the dummy word lines. Alternatively, the number of pages corresponding to the memory cells connected to the dummy word lines may be smaller than the number of pages corresponding to memory cells connected to normal word lines. A voltage level applied to the dummy word lines may differ from a voltage level applied to the normal word lines, and thus an influence of a non-uniform channel width between the lower channel LCH and the upper channel UCH on an operation of the memory device may be reduced.

Meanwhile, it is illustrated in A2 that the number of lower word lines 331 and 332 penetrated by the lower channel LCH is smaller than the number of upper word lines 333 to 338 penetrated by the upper channel UCH. However, this is illustrative, and the present disclosure is not limited thereto. In another example, the number of lower word lines penetrated by the lower channel LCH may be equal to or larger than the number of upper word lines penetrated by the upper channel UCH. Furthermore, the above-described structure and connection relationship of the channel structure CH disposed in the first cell region CELL1 may be identically applied to the channel structure CH disposed in the second cell region CELL2.

In the bit line bonding region BLBA, a first through-electrode THV1 may be provided in the first cell region CELL1, and a second through-electrode THV2 may be provided in the second cell region CELL2. As illustrated in FIG. 20, the first through-electrode THV1 may penetrate the common source line 320 and the plurality of word lines 330. However, this is illustrative, and the first through-electrode THV1 may additionally penetrate the second substrate 310. The first through-electrode THV1 may include a conductive material. Alternatively, the first through-electrode THV1 may include a conductive material surrounded by an insulating material. The second through-electrode THV2 may have the same shape and structure as the first through-electrode THV1.

In some implementations, the first through-electrode THV1 and the second through-electrode THV2 may be electrically connected through a first through-metal pattern 372d and a second through-metal pattern 472d. The first through-metal pattern 372d may be formed on a lower side of the first upper chip including the first cell region CELL1, and the second through-metal pattern 472d may be formed on an upper side of the second upper chip including the second cell region CELL2. The first through-electrode THV1 may be electrically connected with the first metal line 350c and the second metal line 360c. For example, the second through-electrode THV2 may be electrically connected with metal lines 450c and 460c. A lower VIA 371d may be formed between the first through-electrode THV1 and the first through-metal pattern 372d, and an upper VIA 471d may be formed between the second through-electrode THV2 and the second through-metal pattern 472d. The first through-metal pattern 372d and the second through-metal pattern 472d may be connected by a bonding method.

Furthermore, in the bit line bonding region BLBA, an upper metal pattern 252 may be formed on the uppermost metal layer of the peripheral circuit region PERI, and an upper metal pattern 392 having the same shape as the upper metal pattern 252 may be formed on the uppermost metal layer of the first cell region CELL1. The upper metal pattern 392 of the first cell region CELL1 and the upper metal pattern 252 of the peripheral circuit region PERI may be electrically connected to each other by a bonding method. In the bit line bonding region BLBA, the bit line 360c may be electrically connected with a page buffer included in the peripheral circuit region PERI. For example, a portion of the circuit elements 220c of the peripheral circuit region PERI may provide a page buffer, and the bit line 360c may be electrically connected with the circuit elements 220c providing the page buffer through an upper bonding metal 370c of the first cell region CELL1 and an upper bonding metal 270c of the peripheral circuit region PERI.

Continuously referring to FIG. 20, in the word line bonding region WLBA, the word lines 330 of the first cell region CELL1 may extend in a second direction (an X-axis direction) parallel to the upper surface of the second substrate 310 and may be connected with a plurality of cell contact plugs 340 (341 to 347). A first metal line 350b and a second metal line 360b may be sequentially connected to upper portions of the cell contact plugs 340 connected to the word lines 330. In the word line bonding region WLBA, the cell contact plugs 340 may be connected with the peripheral circuit region PERI through an upper bonding metal 370b of the first cell region CELL1 and an upper bonding metal 270b of the peripheral circuit region PERI.

The cell contact plugs 340 may be electrically connected with a row decoder included in the peripheral circuit region PERI. For example, a portion of the circuit elements 220b of the peripheral circuit region PERI may provide a row decoder, and the cell contact plugs 340 may be electrically connected with the circuit elements 220b providing the row decoder through the upper bonding metal 370b of the first cell region CELL1 and the upper bonding metal 270b of the peripheral circuit region PERI. In some implementations, an operating voltage of the circuit elements 220b that provide the row decoder may differ from an operating voltage of the circuit elements 220c that provide the page buffer. For example, the operating voltage of the circuit elements 220c that provide the page buffer may be greater than the operating voltage of the circuit elements 220b that provide the row decoder.

Likewise, in the word line bonding region WLBA, the word lines 430 of the second cell region CELL2 may extend in the second direction (the X-axis direction) parallel to the upper surface of the third substrate 410 and may be connected with a plurality of cell contact plugs 441 to 447 (hereinafter collectively referred to as “440”). The cell contact plugs 440 may be connected with the peripheral circuit region PERI through an upper metal pattern of the second cell region CELL2, a lower metal pattern and an upper metal pattern of the first cell region CELL1, and a cell contact plug 348.

In the word line bonding region WLBA, the upper bonding metal 370b may be formed in the first cell region CELL1, and the upper bonding metal 270b may be formed in the peripheral circuit region PERI. The upper bonding metal 370b of the first cell region CELL1 and the upper bonding metal 270b of the peripheral circuit region PERI may be electrically connected to each other by a bonding method. The upper bonding metal 370b and the upper bonding metal 270b may be formed of aluminum, copper, or tungsten.

In the external pad bonding region PA, a lower metal pattern 371e may be formed on a lower portion of the first cell region CELL1, and an upper metal pattern 472a may be formed on an upper portion of the second cell region CELL2. The lower metal pattern 371e of the first cell region CELL1 and the upper metal pattern 472a of the second cell region CELL2 may be connected by a bonding method in the external pad bonding region PA. Likewise, an upper metal pattern 372a may be formed on an upper portion of the first cell region CELL1, and an upper metal pattern 272a may be formed on an upper portion of the peripheral circuit region PERI. The upper metal pattern 372a of the first cell region CELL1 and the upper metal pattern 272a of the peripheral circuit region PERI may be connected to each other by a bonding method.

Common source line contact plugs 380 and 480 may be disposed in the external pad bonding region PA. The common source line contact plugs 380 and 480 may be formed of a conductive material, such as metal, a metal compound, or doped poly-silicon. The common source line contact plug 380 of the first cell region CELL1 may be electrically connected with the common source line 320, and the common source line contact plug 480 of the second cell region CELL2 may be electrically connected with the common source line 420. A first metal line 350a and a second metal line 360a may be sequentially stacked on an upper portion of the common source line contact plug 380 of the first cell region CELL1, and a first metal line 450a and a second metal line 460a may be sequentially stacked on an upper portion of the common source line contact plug 480 of the second cell region CELL2.

Input/output pads 205, 405, and 406 may be disposed in the external pad bonding region PA. Referring to FIG. 20, a lower insulating layer 201 may cover a lower surface of the first substrate 210, and the first input/output pad 205 may be formed on the lower insulating layer 201. The first input/output pad 205 may be connected with at least one of the plurality of circuit elements 220a disposed in the peripheral circuit region PERI through a first input/output contact plug 203 and may be separated from the first substrate 210 by the lower insulating layer 201. In addition, a side insulating layer may be disposed between the first input/output contact plug 203 and the first substrate 210 and may electrically isolate the first input/output contact plug 203 from the first substrate 210.

An upper insulating layer 401 may be formed on the third substrate 410 to cover the upper surface of the third substrate 410. The second input/output pad 405 and/or the third input/output pad 406 may be disposed on the upper insulating layer 401. The second input/output pad 405 may be connected with at least one of the plurality of circuit elements 220a disposed in the peripheral circuit region PERI through second input/output contact plugs 403 and 303, and the third input/output pad 406 may be connected with at least one of the plurality of circuit elements 220a disposed in the peripheral circuit region PERI through third input/output contact plugs 404 and 304.

In some implementations, the third substrate 410 may not be disposed in the regions in which the input/output contact plugs are disposed. For example, as illustrated in B, the third input/output contact plug 404 may be separated from the third substrate 410 in a direction parallel to the upper surface of the third substrate 410, may penetrate an interlayer insulating layer 415 of the second cell region CELL2, and may be connected to the third input/output pad 406. In this case, the third input/output contact plug 404 may be formed through various processes.

For example, as illustrated in B1 (as an alternative example of region B), the third input/output contact plug 404 may extend in the third direction (the Z-axis direction) and may have an increasing diameter toward the upper insulating layer 401. That is, while the channel structure CH described with reference to A1 has a decreasing diameter toward the upper insulating layer 401, the third input/output contact plug 404 may have an increasing diameter toward the upper insulating layer 401. For example, the third input/output contact plug 404 may be formed after the second cell region CELL2 and the first cell region CELL1 are coupled by a bonding method.

For example, as illustrated in B2 (as an alternative example of region B), the third input/output contact plug 404 may extend in the third direction (the Z-axis direction) and may have a decreasing diameter toward the upper insulating layer 401. That is, likewise to the channel structure CH, the third input/output contact plug 404 may have a decreasing diameter toward the upper insulating layer 401. For example, the third input/output contact plug 404 may be formed together with the cell contact plugs 440 before the second cell region CELL2 and the first cell region CELL1 are coupled by a bonding method.

In some implementations, an input/output contact plug may be disposed to overlap the third substrate 410. For example, as illustrated in C, the second input/output contact plug 403 may be formed through the interlayer insulating layer 415 of the second cell region CELL2 in the third direction (the Z-axis direction) and may be electrically connected to the second input/output pad 405 through the third substrate 410. In this case, a connection structure of the second input/output contact plug 403 and the second input/output pad 405 may be implemented in various ways.

For example, as illustrated in C1 (as an alternative example of region C), an opening 408 may be formed through the third substrate 410, and the second input/output contact plug 403 may be directly connected to the second input/output pad 405 through the opening 408 formed in the third substrate 410. In this case, as illustrated in C1, the second input/output contact plug 403 may have an increasing diameter toward the second input/output pad 405. However, this is illustrative, and the second input/output contact plug 403 may have a decreasing diameter toward the second input/output pad 405.

For example, as illustrated in C2 (as an alternative example of region C), the opening 408 may be formed through the third substrate 410, and a contact 407 may be formed in the opening 408. One end portion of the contact 407 may be connected to the second input/output pad 405, and an opposite end portion of the contact 407 may be connected to the second input/output contact plug 403. Accordingly, the second input/output contact plug 403 may be electrically connected to the second input/output pad 405 through the contact 407 in the opening 408. In this case, as illustrated in C2, the contact 407 may have an increasing diameter toward the second input/output pad 405, and the second input/output contact plug 403 may have a decreasing diameter toward the second input/output pad 405. For example, the third input/output contact plug 404 may be formed together with the cell contact plugs 440 before the second cell region CELL2 and the first cell region CELL1 are coupled by a bonding method, and the contact 407 may be formed after the second cell region CELL2 and the first cell region CELL1 are coupled by the bonding method.

For example, as illustrated in C3 (as an alternative example of region C), a stopper 409 may be additionally formed on an upper surface of the opening 408 of the third substrate 410. The stopper 409 may be a metal line formed on the same layer as the common source line 420. However, this is illustrative, and the stopper 409 may be a metal line formed on the same layer as at least one of the word lines 430. The second input/output contact plug 403 may be electrically connected to the second input/output pad 405 through the contact 407 and the stopper 409.

Meanwhile, similarly to the second and third input/output contact plugs 403 and 404 of the second cell region CELL2, the second and third input/output contact plugs 303 and 304 of the first cell region CELL1 may have a decreasing diameter toward the lower metal pattern 371e, or may have an increasing diameter toward the lower metal pattern 371e.

Meanwhile, in some implementations, a slit 411 may be formed in the third substrate 410. For example, the slit 411 may be formed at any position in the external pad bonding region PA. For example, as illustrated in D, the slit 411 may be located between the second input/output pad 405 and the cell contact plugs 440 when viewed on a plane. However, this is illustrative, and the slit 411 may be formed such that the second input/output pad 405 is located between the slit 411 and the cell contact plugs 440 when viewed on the plane.

For example, as illustrated in D1 (as an alternative example of region D), the slit 411 may be formed through the third substrate 410. For example, the slit 411 may be used to prevent the third substrate 410 from being finely cracked when the opening 408 is formed. However, this is illustrative, and the slit 411 may be formed to have a depth ranging from about 60% to about 70% of the thickness of the third substrate 410.

For example, as illustrated in D2 (as an alternative example of region D), a conductive material 412 may be formed in the slit 411. For example, the conductive material 412 may be used to discharge a leakage current generated while circuit elements in the external pad bonding region PA are driven. In this case, the conductive material 412 may be connected to an external ground line.

For example, as illustrated in D3 (as an alternative example of region D), an insulating material 413 may be formed in the slit 411. For example, the insulating material 413 may be formed to electrically isolate the second input/output pad 405 and the second input/output contact plug 403 disposed in the external pad bonding region PA from the word line bonding region WLBA. An influence of a voltage provided through the second input/output pad 405 on a metal layer disposed on the third substrate 410 in the word line bonding region WLBA may be interrupted by forming the insulating material 413 in the slit 411.

Meanwhile, in some implementations, the first to third input/output pads 205, 405, and 406 may be selectively formed. For example, the memory device 500 may be implemented to include only the first input/output pad 205 disposed on the lower insulating layer 201, only the second input/output pad 405 disposed on the third substrate 410, or only the third input/output pad 406 disposed on the upper insulating layer 401.

Meanwhile, in some implementations, at least one of the second substrate 310 of the first cell region CELL1 and the third substrate 410 of the second cell region CELL2 may be used as a sacrificial substrate and may be completely or partially removed before or after a bonding process. An additional layer may be stacked after the removal of the substrate. For example, the second substrate 310 of the first cell region CELL1 may be removed before or after the peripheral circuit region PERI and the first cell region CELL1 are bonded to each other, and an insulating layer for covering an upper surface of the common source line 320 or a conductive layer for connection may be formed. Similarly, the third substrate 410 of the second cell region CELL2 may be removed before or after the first cell region CELL1 and the second cell region CELL2 are bonded to each other, and the upper insulating layer 401 for covering an upper surface of the common source line 420 or a conductive layer for connection may be formed.

In some implementations, the memory device 500 of FIG. 20 may be the memory device 120 described with reference to FIGS. 1 to 19. In some implementations, the ground selection lines or ground selection transistors of the memory device 500 of FIG. 20 may have the GSL coding pattern described with reference to FIGS. 1 to 19, and the GSL coding pattern may be changed or updated under control of the memory device 500 or the controller 110.

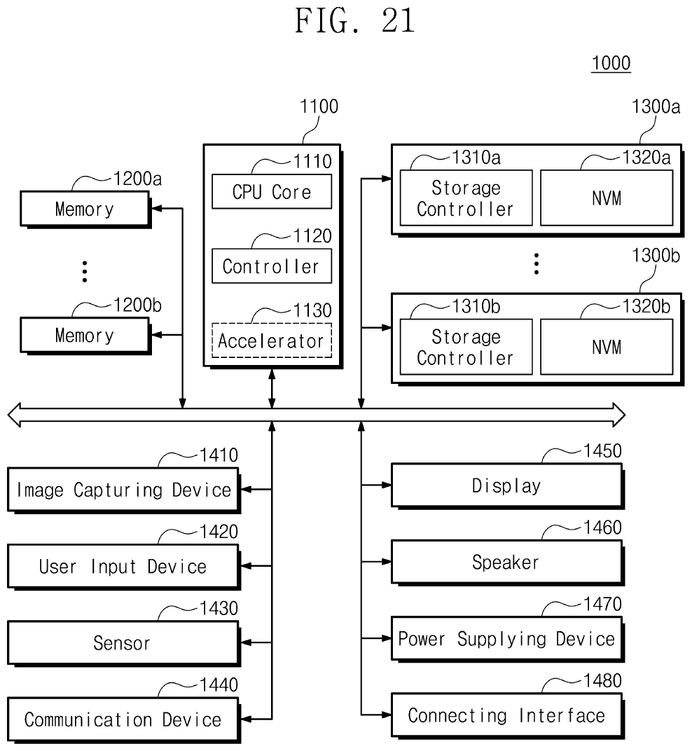

FIG. 21 is a diagram of an example of a system 1000 to which a storage device is applied. The system 1000 of FIG. 21 may basically be a mobile system, such as a portable communication terminal (e.g., a mobile phone), a smartphone, a tablet personal computer (PC), a wearable device, a healthcare device, or an Internet of things (IoT) device. However, the system 1000 of FIG. 21 is not necessarily limited to the mobile system and may be a PC, a laptop computer, a server, a media player, or an automotive device (e.g., a navigation device).

Referring to FIG. 21, the system 1000 may include a main processor 1100, memories (e.g., 1200a and 1200b), and storage devices (e.g., 1300a and 1300b). In addition, the system 1000 may include at least one of an image capturing device 1410, a user input device 1420, a sensor 1430, a communication device 1440, a display 1450, a speaker 1460, a power supplying device 1470, and a connecting interface 1480.

The main processor 1100 may control all operations of the system 1000, more specifically, operations of other components included in the system 1000. The main processor 1100 may be implemented as a general-purpose processor, a dedicated processor, or an application processor.

The main processor 1100 may include at least one CPU core 1110 and further include a controller 1120 configured to control the memories 1200a and 1200b and/or the storage devices 1300a and 1300b. In some implementations, the main processor 1100 may further include an accelerator 1130, which is a dedicated circuit for a high-speed data operation, such as an artificial intelligence (AI) data operation. The accelerator 1130 may include a graphics processing unit (GPU), a neural processing unit (NPU) and/or a data processing unit (DPU) and be implemented as a chip that is physically separate from the other components of the main processor 1100.

The memories 1200a and 1200b may be used as main memory devices of the system 1000. Although each of the memories 1200a and 1200b may include a volatile memory, such as static random access memory (SRAM) and/or dynamic RAM (DRAM), each of the memories 1200a and 1200b may include non-volatile memory, such as a flash memory, phase-change RAM (PRAM) and/or resistive RAM (RRAM). The memories 1200a and 1200b may be implemented in the same package as the main processor 1100.

The storage devices 1300a and 1300b may serve as non-volatile storage devices configured to store data regardless of whether power is supplied thereto, and have larger storage capacity than the memories 1200a and 1200b. The storage devices 1300a and 1300b may respectively include storage controllers (STRG CTRL) 1310a and 1310b and NVMs (Non-Volatile Memories) 1320a and 1320b configured to store data via the control of the storage controllers 1310a and 1310b. Although the NVMs 1320a and 1320b may include flash memories having a two-dimensional (2D) structure or a three-dimensional (3D) V-NAND structure, the NVMs 1320a and 1320b may include other types of NVMs, such as PRAM and/or RRAM.

The storage devices 1300a and 1300b may be physically separated from the main processor 1100 and included in the system 1000 or implemented in the same package as the main processor 1100. In addition, the storage devices 1300a and 1300b may have types of solid-state devices (SSDs) or memory cards and be removably combined with other components of the system 1000 through an interface, such as the connecting interface 1480 that will be described below. The storage devices 1300a and 1300b may be devices to which a standard protocol, such as a universal flash storage (UFS), an embedded multi-media card (eMMC), or a non-volatile memory express (NVMe), is applied, without being limited thereto.

The image capturing device 1410 may capture still images or moving images. The image capturing device 1410 may include a camera, a camcorder, and/or a webcam.

The user input device 1420 may receive various types of data input by a user of the system 1000 and include a touch pad, a keypad, a keyboard, a mouse, and/or a microphone.

The sensor 1430 may detect various types of physical quantities, which may be obtained from the outside of the system 1000, and convert the detected physical quantities into electric signals. The sensor 1430 may include a temperature sensor, a pressure sensor, an illuminance sensor, a position sensor, an acceleration sensor, a biosensor, and/or a gyroscope sensor.

The communication device 1440 may transmit and receive signals between other devices outside the system 1000 according to various communication protocols. The communication device 1440 may include an antenna, a transceiver, and/or a modem.

The display 1450 and the speaker 1460 may serve as output devices configured to respectively output visual information and auditory information to the user of the system 1000.

The power supplying device 1470 may appropriately convert power supplied from a battery embedded in the system 1000 and/or an external power source, and supply the converted power to each of components of the system 1000.

The connecting interface 1480 may provide connection between the system 1000 and an external device, which is connected to the system 1000 and capable of transmitting and receiving data to and from the system 1000. The connecting interface 1480 may be implemented by using various interface schemes, such as advanced technology attachment (ATA), serial ATA (SATA), external SATA (e-SATA), small computer small interface (SCSI), serial attached SCSI (SAS), peripheral component interconnection (PCI), PCI express (PCIe), NVMe, IEEE 1394, a universal serial bus (USB) interface, a secure digital (SD) card interface, a multi-media card (MMC) interface, an eMMC interface, a UFS interface, an embedded UFS (eUFS) interface, and a compact flash (CF) card interface.

In some implementations, the storage devices 1300a and 1300b of FIG. 21 may be the storage device 100 described with reference to FIGS. 1 to 19 or may include the controller 110 and the memory device 120 described with reference to FIGS. 1 to 19. The storage devices 1300a and 1300b of FIG. 21 may change or update GSL coding patterns of memory blocks included in the storage devices 1300a and 1300b, based on the method described with reference to FIGS. 1 to 19.

According to the present disclosure, while a storage device is operating, GSL coding patterns of memory blocks may be changed or updated. For example, in the early part of the lifetime of the storage device or a memory device, ground selection transistors of memory blocks may be programmed based on a GSL coding pattern relatively robust for the hot electron injection (HCI), and in the latter part of the lifetime of the storage device or the memory device, the ground selection transistors of the memory blocks may be programmed based on a GSL coding pattern relatively robust for retention characteristic. In this case, because the increase or decrease in threshold voltages of the ground selection transistors capable of occurring depending on a lifetime period of the memory device is prevented, the reliability and performance of the memory device are improved.

According to an embodiment of the present disclosure, a memory device may include a substrate; a first memory block positioned on the substrate; and a peripheral circuit configured to control the first memory block, wherein the first memory block includes a plurality of cell strings provided on the substrate between a common source line and a first bit line, the plurality of cell strings being connected with a plurality of ground selection lines, wherein each cell string of the plurality of cell strings includes a plurality of ground selection transistors connected with the plurality of ground selection lines, and wherein the peripheral circuit is configured to, based on a program and erase cycle of the first memory block being a first reference value, control a threshold voltage of each of the plurality of ground selection transistors.

According to an embodiment of the present disclosure, a storage device may include a memory device including a first memory block connected with a plurality of ground selection lines; and a controller configured to control the memory device, wherein the controller is configured to, based on a program and erase cycle of the first memory block being a first reference value, perform a program operation for the plurality of ground selection lines to thereby enable a GSL coding pattern of the plurality of ground selection lines to be updated.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the present disclosure has been described with reference to implementations thereof, it will be apparent to those of ordinary skill in the art that various changes and modifications may be made thereto without departing from the spirit and scope of the present disclosure as set forth in the following claims.

1. An operation method of a memory device, the method comprising:
controlling, based on a 0-th bias condition, a first memory block, the 0-th bias condition corresponding to a 0-th GSL coding pattern of a plurality of ground selection lines connected with the first memory block;
based on a program and erase cycle of the first memory block being a first reference value, programming the plurality of ground selection lines of the first memory block to a first GSL coding pattern; and
controlling, based on a first bias condition corresponding to the first GSL coding pattern, the first memory block,
wherein each of the 0-th bias condition and the first bias condition indicates voltages that are applied to the plurality of ground selection lines connected with the first memory block, respectively.

2. The method of claim 1,
wherein, based on the plurality of ground selection lines of the first memory block having the 0-th GSL coding pattern,
at least one first ground selection transistor connected with a first ground selection line among the plurality of ground selection lines has a first threshold voltage state,
at least one second ground selection transistor connected with a second ground selection line among the plurality of ground selection lines has the first threshold voltage state, and
a plurality of third ground selection transistors connected with a third ground selection line have a second threshold voltage state lower than the first threshold voltage state, the third ground selection line being between the first ground selection line and the second ground selection line, and
wherein, based on the plurality of ground selection lines of the first memory block having the first GSL coding pattern,
the at least one first ground selection transistor connected with the first ground selection line has the first threshold voltage state,
the at least one second ground selection transistor connected with the second ground selection lines has the first threshold voltage state, and
at least one third ground selection transistor among the plurality of third ground selection transistors connected with the third ground selection line has the first threshold voltage state.

3. The method of claim 2, wherein programming the plurality of ground selection lines of the first memory block to the first GSL coding pattern based on the program and erase cycle of the first memory block being the first reference value includes:
performing a program operation for the third ground selection line without erasing the first memory block such that the at least one third ground selection transistor is programmed to the first threshold voltage state.

4. The method of claim 2, wherein controlling the first memory block based on the 0-th bias condition includes:
based on a first cell string among a plurality of cell strings of the first memory block being selected, applying a first voltage to the first ground selection line, applying a second voltage higher than the first voltage to the second ground selection line, and applying a third voltage higher than the first voltage and lower than the second voltage to the third ground selection line.

5. The method of claim 4, wherein controlling the first memory block based on the first bias condition includes:
based on the first cell string among the plurality of cell strings of the first memory block being selected, applying the first voltage to the first ground selection line, applying the second voltage higher than the first voltage to the second ground selection line, and applying the second voltage to the third ground selection line.

6. The method of claim 2, wherein programming the plurality of ground selection lines of the first memory block to the first GSL coding pattern based on the program and erase cycle of the first memory block being the first reference value includes:
performing a first threshold voltage check operation for the plurality of ground selection lines of the first memory block; and
based on the first threshold voltage check operation being failed, programming the plurality of ground selection lines of the first memory block to the first GSL coding pattern.

7. The method of claim 6, wherein the first threshold voltage check operation includes detecting a number of ground selection transistors having a threshold voltage lower than a lower limit level of the first threshold voltage state from a plurality of ground selection transistors in the first threshold voltage state.

8. The method of claim 1, wherein, based on the plurality of ground selection lines of the first memory block having the 0-th GSL coding pattern, a plurality of cell strings of the first memory block are controlled in n units,
wherein, based on the plurality of ground selection lines of the first memory block having the first GSL coding pattern, the plurality of cell strings of the first memory block are controlled in m units, and
wherein n and m are different positive integers.

9. The method of claim 1, further comprising:
based on the program and erase cycle of the first memory block being the first reference value, programming a plurality of ground selection lines of a second memory block to the first GSL coding pattern, the second memory block being different from the first memory block; and
controlling the second memory block based on the first bias condition corresponding to the first GSL coding pattern.

10. The method of claim 1, further comprising:
based on the program and erase cycle of the first memory block being a second reference value, programming the plurality of ground selection lines of the first memory block to a second GSL coding pattern; and
controlling the first memory block based on a second bias condition corresponding to the second GSL coding pattern.

11. The method of claim 9, wherein the first memory block and the second memory block are included in a first super block.

12. The method of claim 1, wherein programming the plurality of ground selection lines of the first memory block to the first GSL coding pattern based on the program and erase cycle of the first memory block being the first reference value includes:
performing an erase operation for the first memory block; and
programming the plurality of ground selection lines of the first memory block to the first GSL coding pattern.

13. The method of claim 1, wherein, based on the plurality of ground selection lines of the first memory block having the 0-th GSL coding pattern, at least one of the plurality of ground selection lines are a dummy ground selection line, and
wherein, based on the plurality of ground selection lines of the first memory block having the first GSL coding pattern, in each cell string of a plurality of cell strings of the first memory block, at least two adjacent ground selection transistors have a first threshold voltage state.

14. An operation method of a memory device, the method comprising:
performing an operation for a first memory block having a 0-th GSL coding pattern;
based on a program and erase cycle of the first memory block being a first reference value, updating the 0-th GSL coding pattern of the first memory block to a first GSL coding pattern; and
performing an operation for the first memory block having the first GSL coding pattern,
wherein, in the first memory block having the 0-th GSL coding pattern, at least one first ground selection transistor connected with a first ground selection line has a first threshold voltage state, at least one second ground selection transistor connected with a second ground selection line has the first threshold voltage state, and a plurality of third ground selection transistors connected with a third ground selection line have a second threshold voltage state lower than the first threshold voltage state, the third ground selection line being between the first ground selection line and the second ground selection line, and
wherein, in the first memory block having the first GSL coding pattern, the at least one first ground selection transistor connected with the first ground selection line has the first threshold voltage state, the at least one second ground selection transistor connected with the second ground selection line has the first threshold voltage state, and at least one third ground selection transistor among the plurality of third ground selection transistors connected with the third ground selection line has the first threshold voltage state.

15. The method of claim 14, wherein performing the operation for the first memory block having the 0-th GSL coding pattern includes:
based on a first cell string among a plurality of cell strings of the first memory block being selected, applying a first voltage to the first ground selection line, applying a second voltage higher than the first voltage to the second ground selection line, and applying a third voltage higher than the first voltage and lower than the second voltage to the third ground selection line, and
wherein performing the operation for the first memory block having the first GSL coding pattern include:
based on the first cell string among the plurality of cell strings of the first memory block being selected, applying the first voltage to the first ground selection line, applying the second voltage to the second ground selection line, and applying the second voltage to the third ground selection line.

16. The method of claim 15, wherein performing the operation for the first memory block having the 0-th GSL coding pattern includes:
based on a second cell string among the plurality of cell strings of the first memory block being selected, applying the second voltage to the first ground selection line, applying the first voltage to the second ground selection line, and applying the third voltage to the third ground selection line, and
wherein performing the operation for the first memory block having the first GSL coding pattern include:
based on the second cell string among the plurality of cell strings of the first memory block being selected, applying the second voltage to the first ground selection line, applying the first voltage to the second ground selection line, and applying the second voltage to the third ground selection line.

17. The method of claim 14, wherein the second ground selection line and the third ground selection line are adjacent to each other, and
wherein the first ground selection line and the third ground selection line are adjacent to each other.

18. The method of claim 14, further comprising:
performing an operation for a second memory block having the 0-th GSL coding pattern;
based on a program and erase cycle of the second memory block being the first reference value, updating the 0-th GSL coding pattern of the second memory block to the first GSL coding pattern; and
performing an operation for the second memory block having the first GSL coding pattern.

19. An operation method of a memory device, the method comprising:
performing an operation for a first memory block having a 0-th GSL coding pattern;
based on a program and erase cycle of the first memory block being a first reference value, updating the 0-th GSL coding pattern of the first memory block to a first GSL coding pattern; and
performing an operation for the first memory block having the first GSL coding pattern,
wherein, based on the first memory block having the 0-th GSL coding pattern, at least one third ground selection line among a plurality of ground selection lines connected with the first memory block is a dummy ground selection line controlled regardless of a selected cell string among a plurality of cell strings of the first memory block, the at least one third ground selection line being between a first ground selection line and a second ground selection line, and
wherein, based on the first memory block having the first GSL coding pattern, the at least one third ground selection line is a coding ground selection line controlled based on the selected cell string among the plurality of cell strings of the first memory block.

20. The method of claim 19, wherein, based on the first memory block having the first GSL coding pattern, in each cell string of the plurality of cell strings of the first memory block, at least two adjacent ground selection transistors have a first threshold voltage state, and remaining ground selection transistors have a second threshold voltage state lower than the first threshold voltage state.

21. (canceled)

22. (canceled)
